(19) United States
(12) Patent Application Publication
(10) Pub. No.: US 2026/0026308 A1
(43) Pub. Date: Jan. 22, 2026

(54) MANUFACTURING METHOD FOR SEMICONDUCTOR DEVICE AND WAFER SUPPORT STRUCTURE

(71) Applicant: ROHM CO., LTD., Kyoto-shi (JP)

(72) Inventor: Yuichi NAKAO, Kyoto-shi (JP)

(73) Assignee: ROHM CO., LTD., Kyoto-shi (JP)

(21) Appl. No.: 19/344,591

(22) Filed: Sep. 30, 2025

Related U.S. Application Data
(63) Continuation of application No. PCT/JP2024/012700, filed on Mar. 28, 2024.

(30) Foreign Application Priority Data
Mar. 30, 2023 (JP) 2023-056212

(51) Int. Cl. H01L 21/683; H01L 21/304; H01L 21/66; H01L 21/78

(52) U.S. Cl. CPC H01L 21/6836; H01L 21/304; H01L 21/78; H01L 22/34; H01L 2221/68327; H01L 2221/68386

(57) ABSTRACT

A manufacturing method for a semiconductor device includes a preparation step of preparing a wafer that has a first surface on one side and a second surface on the other side, a first supporting step of supporting the wafer from the first surface side by a first member of a plate shape, a thinning step of thinning the wafer in a state where the wafer is supported by the first member, a second supporting step of supporting the wafer from a peripheral edge portion side of the second surface by a second member of a plate shape that exposes an inner portion of the second surface after the thinning step, and a removing step of removing the first member from the first surface side in a state where the wafer is supported by the second member.

### CROSS-REFERENCE TO RELATED APPLICATIONS

The present application is a bypass continuation of International Patent Application No. PCT/JP2024/012700 filed on Mar. 28, 2024, which claims priority to Japanese Patent Application No. 2023-056212 filed on Mar. 30, 2023 in the Japan Patent Office, and the entire contents of these applications are hereby incorporated herein by reference.

### BACKGROUND

### 1. Field of the disclosure

The present disclosure relates to a manufacturing method for a semiconductor device and a wafer support structure.

### 2. Description of the Related Art

US2014/0130969A1 discloses a bonding method and a peeling method for a wafer supporting an ultrathin layer.

### BRIEF DESCRIPTION OF DRAWINGS

FIG. 1 is a plan view illustrating a wafer structure used for manufacturing of a semiconductor device.

FIG. 2 is a cross-sectional view illustrating a wafer structure together with a device structure.

FIG. 3 is an enlarged cross-sectional view illustrating a first example of a peripheral end surface of the wafer structure.

FIG. 4 is an enlarged cross-sectional view illustrating a second example of the peripheral end surface of the wafer structure.

FIG. 5 is a plan view of a main portion illustrating an example of a device structure.

FIG. 6 is a cross-sectional view taken along line VI-VI illustrated in FIG. 5.

FIG. 7 is a plan view illustrating a first supporting member used for manufacturing of a semiconductor device.

FIG. 8 is a cross-sectional view illustrating the first supporting member.

FIG. 9 is a plan view illustrating a second supporting member used for manufacturing of a semiconductor device.

FIG. 10 is a cross-sectional view illustrating the second supporting member.

FIG. 11 is a flowchart illustrating an example of a manufacturing method for a semiconductor device according to a specific embodiment.

FIGS. 12A to 12L are cross-sectional views illustrating an example of the manufacturing method for the semiconductor device according to FIG. 11.

FIG. 13 is an enlarged cross-sectional view illustrating a removing step of a peripheral end surface.

FIG. 14 is an enlarged cross-sectional view illustrating a supporting step of a first supporting member.

FIG. 15 is an enlarged cross-sectional view illustrating a thinning step of the wafer structure.

FIG. 16 is an enlarged cross-sectional view illustrating a forming step of an electrode.

FIG. 17 is an enlarged cross-sectional view illustrating a supporting step of a second supporting member.

FIGS. 18A to 18C are cross-sectional views illustrating another example of a dicing step.

FIG. 19 is a plan view illustrating a wafer structure (device structure) according to another example.

FIG. 20 is a cross-sectional view illustrating a wafer structure (device structure) according to another example.

FIG. 21 is a plan view illustrating a wafer (mark) according to another example.

FIG. 22 is a plan view illustrating a second supporting member that can be used in combination with a wafer (mark) according to another example.

### DETAILED DESCRIPTION OF THE PREFERRED EMBODIMENTS

Hereinafter, specific embodiments will be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in the present specification, the wording includes a numerical value (shape) equal to a numerical value (shape) of a comparison target and also includes numerical errors (shape errors) in a range of ±10% with the numerical value (shape) of the comparison target as a reference. Although the wordings “first,” “second,” and the like are used in the following description, these are symbols attached to names of respective structures in order to clarify the order of description, and are not attached with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

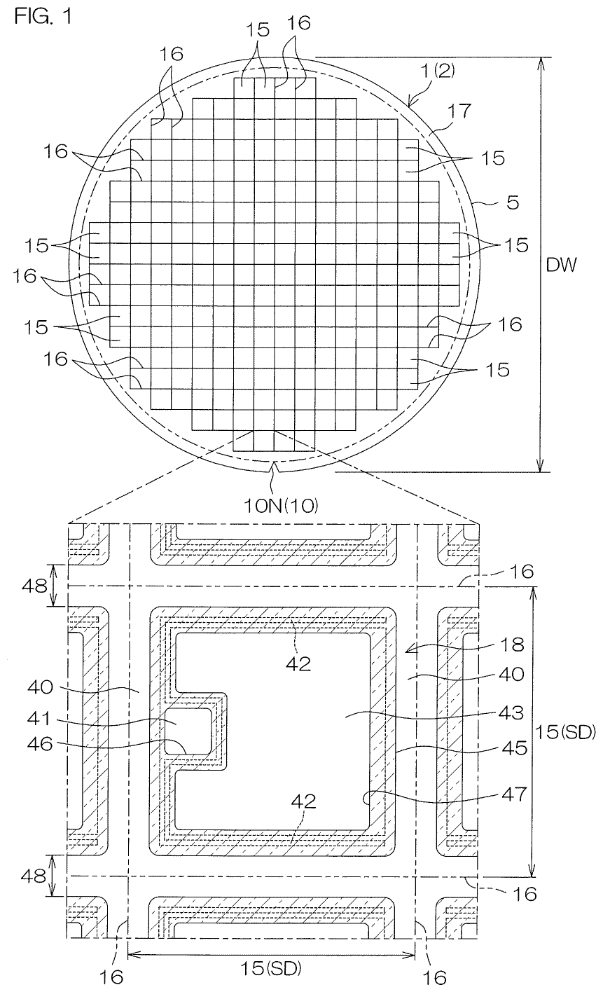

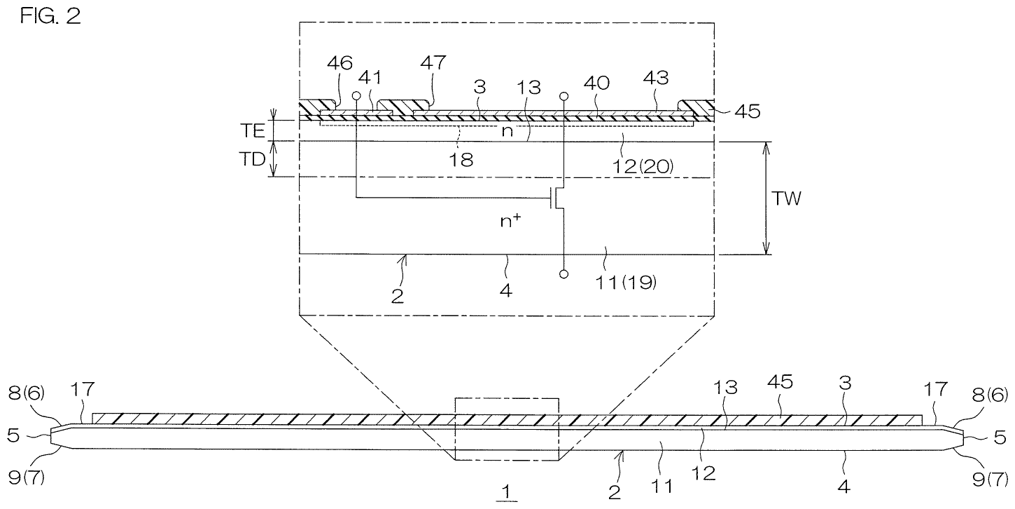

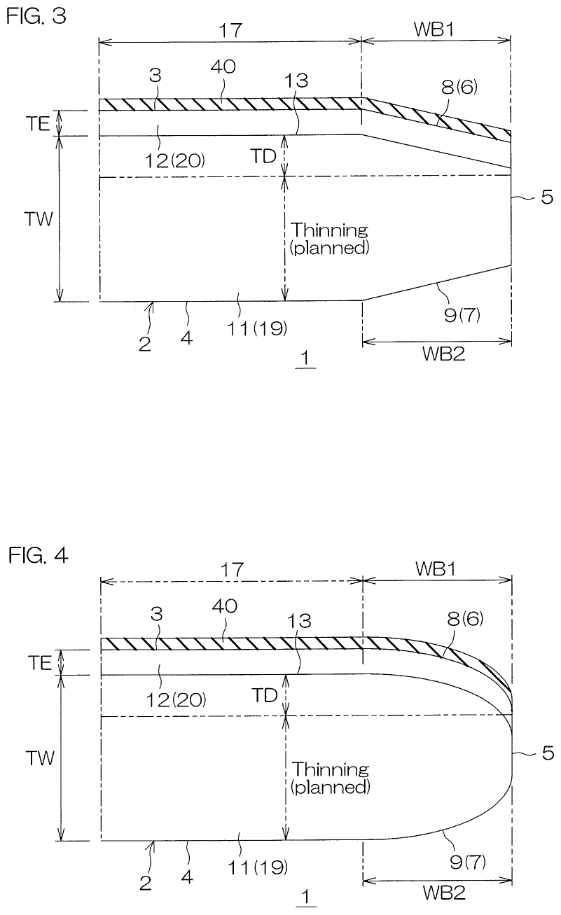

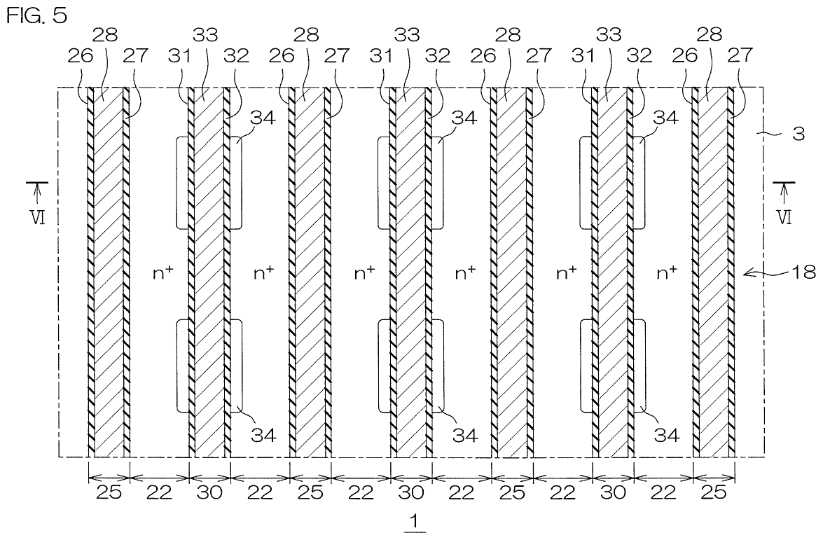

FIG. 1 is a plan view illustrating a wafer structure 1 used for manufacturing of a semiconductor device SD. FIG. 2 is a cross-sectional view illustrating the wafer structure 1 together with a device structure 18. FIG. 3 is an enlarged cross-sectional view illustrating a first example of a peripheral end surface 5 of the wafer structure 1. FIG. 4 is an enlarged cross-sectional view illustrating a second example of the peripheral end surface 5 of the wafer structure 1.

Referring to FIG. 1 and FIG. 2, a wafer structure 1 includes a wafer 2 formed in a flat disk shape. The wafer 2 may be formed in a flat rectangular parallelepiped shape. The wafer 2 includes an SiC single crystal as an example of a wide bandgap semiconductor single crystal. That is, the wafer 2 is made of an SiC wafer. The wide bandgap semiconductor single crystal is a semiconductor single crystal having a bandgap higher than a bandgap of an Si single crystal.

In this embodiment, the chip 2 is made of an SiC single crystal, which is a hexagonal crystal, and is formed in a rectangular parallelepiped shape. The hexagonal SiC single crystal includes a plurality of types of polytypes including 2 hexagonal (H)-SiC single crystal, 4H-SiC single crystal, 6H-SiC single crystal, and the like. In this embodiment, an example in which the chip 2 includes a 4H-SiC single crystal is given, but the chip 2 may include another polytype crystal.

The wafer 2 has a first surface 3 on one side, a second surface 4 on the other side, and a peripheral end surface 5 that connects the first surface 3 and the second surface 4. The first surface 3 is a device surface, and extends to be flat in a horizontal direction. The second surface 4 is a non-device surface, and extends to be flat in the horizontal direction. That is, the second surface 4 extends to be substantially parallel to the first surface 3. The peripheral end surface 5 extends in a vertical direction between the first surface 3 and the second surface 4.

Preferably, the first surface 3 and the second surface 4 are formed by c-planes of the SiC single crystal. In this case, preferably, the first surface 3 is formed by a silicon plane (a (0001) plane) of the SiC single crystal, and the second surface 4 is formed by a carbon plane (a (000-1) plane) of the SiC single crystal.

The wafer 2 (the first surface 3 and the second surface 4) has an off angle inclined at a predetermined angle in a predetermined off direction with respect to the c-plane of the SiC single crystal. That is, a c-axis ((0001) axis) of the SiC single crystal is inclined by the off angle toward the off direction from the vertical axis. Also, the c-plane of the SiC single crystal is inclined by the off angle with respect to the horizontal plane.

Preferably, the off direction is an a-axis direction ([11-20] direction) of the SiC single crystal. The off angle may be larger than 0° and equal to or smaller than 10°. The off angle may have a value in at least one range among a range larger than 0° and equal to or smaller 1°, a range of 1° or larger and 2.5° or smaller, a range of 2.5° or larger and 5° or smaller, a range of 5° or larger and 7.5° or smaller, and a range of 7.5° or larger and 10° or smaller.

Preferably, the off angle is equal to or smaller than 5°. It is particularly preferable that the off angle is in a range of 2° or larger and 4.5° or smaller. The off angle is typically set in a range of 4°±0.1°. This specification does not exclude a form in which the off angle is 0° (that is, the first surface 3 is a just surface with respect to the c-plane).

The wafer 2 includes a first corner portion 6 and a second corner portion 7. The first corner portion 6 is a connection portion between the first surface 3 and the peripheral end surface 5. The second corner portion 7 is a connection portion between the second surface 4 and the peripheral end surface 5. In this embodiment, the wafer 2 includes a first bevel portion 8 and a second bevel portion 9.

The first bevel portion 8 is formed in the first corner portion 6 of the first surface 3. The first bevel portion 8 is formed of an inclined portion (inclined surface) inclined obliquely downward from the first surface 3 toward the second surface 4 side in the peripheral edge portion of the first surface 3. Referring to FIG. 3, the first bevel portion 8 may extend in a straight line shape in a cross-sectional view. Referring to FIG. 4, the first bevel portion 8 may extend in an arc shape (circular arc shape) in a cross-sectional view. The first bevel portion 8 has a first bevel width WB1. The first bevel width WB1 may be 0.1 mm or wider and 2 mm or narrower.

The second bevel portion 9 is formed in the second corner portion 7 of the second surface 4. The second bevel portion 9 is formed of an inclined portion (inclined surface) inclined obliquely downward from the second surface 4 toward the first surface 3 side in the peripheral edge portion of the second surface 4. Referring to FIG. 3, the second bevel portion 9 may extend in a straight line shape in a cross-sectional view. Referring to FIG. 4, the second bevel portion 9 may extend in an arc shape (circular arc shape) in a cross-sectional view. The second bevel portion 9 has a second bevel width WB2. The second bevel width WB2 may be 0.1 mm or wider and 2 mm or narrower.

The presence or absence of the first bevel portion 8 and the second bevel portion 9 is arbitrary. Therefore, the wafer 2 that includes the first bevel portion 8 and does not include the second bevel portion 9 may be adopted. In this case, the second corner portion 7 connects the second surface 4 and the peripheral end surface 5 in a substantially perpendicular manner. Also, the wafer 2 that includes the second bevel portion 9 and does not include the first bevel portion 8 may be adopted. In this case, the first corner portion 6 connects the first surface 3 and the peripheral end surface 5 in a substantially perpendicular manner. As a matter of course, the wafer 2 that does not include both of the first bevel portion 8 and the second bevel portion 9 may be adopted.

The wafer 2 has a mark 10 indicating a crystal orientation of the SiC single crystal in the peripheral end surface 5. The mark 10 may indicate either an a-axis direction or an m-axis direction ([1-100] direction). In this embodiment, the mark 10 includes a notched portion 10N. The notched portion 10N may be referred to as an “orientation notch.” The notched portion 10N is formed of a notched portion that is recessed in a tapered shape toward a central portion of the first surface 3 along the a-axis direction or the m-axis direction. A length of the notched portion 10N may be 0.5 mm or longer and 2 mm or shorter.

The wafer 2 may have a wafer diameter DW of 2 inches or larger and 12 inches or smaller (50 mm or larger and 300 mm or smaller) in a plan view. The wafer diameter DW is defined by a length (that is, a diameter) of a chord passing through the center of the wafer 2 outside the mark 10. Preferably, the wafer diameter DW is 6 inches or larger (150 mm or larger). It is particularly preferable that the wafer diameter DW is 8 inches or larger (200 mm or larger).

In this embodiment, the wafer 2 is made of an epitaxial wafer including a wafer body 11 and an epitaxial layer 12. The wafer body 11 is a base material (SiC substrate) including a portion of the wafer 2 other than a surface portion of the first surface 3, and has the off direction and the off angle described above. The wafer body 11 forms the second surface 4, and forms a part or all of the peripheral end surface 5. That is, the wafer body 11 includes the second bevel portion 9 (second corner portion 7) in the peripheral edge portion of the second surface 4 (refer to FIG. 3 and FIG. 4).

The wafer body 11 has a base surface 13 that serves as a base (crystal growth starting point) of the first surface 3 in the surface portion of the first surface 3. The base surface 13 includes the first bevel portion 8 (first corner portion 6) inclined obliquely downward toward the second surface 4 side in the peripheral edge portion of the first surface 3 (refer to FIG. 3 and FIG. 4).

The epitaxial layer 12 is made of an SiC epitaxial layer (SiC semiconductor layer) obtained by crystal-growing an SiC single crystal, which is an example of a wide bandgap semiconductor single crystal, from the wafer body 11, and has the off direction and the off angle described above. The epitaxial layer 12 is crystal-grown starting from the base surface 13, and forms the first surface 3, the surface portion of the first surface 3, and a portion of the peripheral end surface 5.

The epitaxial layer 12 is laminated in a layer shape extending along the base surface 13 in the entire region of the base surface 13. The epitaxial layer 12 forms the first bevel portion 8 (first corner portion 6) in the peripheral edge portion of the base surface 13 (first surface 3), and is inclined obliquely downward toward the second surface 4 side along the first bevel portion 8 (refer to FIG. 3 and FIG. 4). The epitaxial layer 12 may include a portion laminated on the peripheral end surface 5 of the wafer body 11. In this case, the epitaxial layer 12 may include a portion laminated on the second bevel portion 9 of the wafer body 11.

The wafer body 11 may have an initial thickness TW of 250 μm or thicker and 650 μm or thinner. The initial thickness TW may have a value in at least one range among a range of 250 μm or thicker and 300 μm or thinner, 300 μm or thicker and 350 μm or thinner, 350 μm or thicker and 400 μm or thinner, 400 μm or thicker and 450 μm or thinner, 450 μm or thicker and 500 μm or thinner, 500 μm or thicker and 550 μm or thinner, 550 μm or thicker and 600 μm or thinner, and 600 μm or thicker and 650 μm or thinner. The initial thickness TW may be 300 μm or thicker and 600 μm or thinner. The initial thickness TW is typically 340 μm or thicker and 510 μm or thinner.

During a manufacturing process, the wafer body 11 is thinned from the initial thickness TW to a device thickness TD (refer to a two-dotted chain line portion in FIG. 2) thinner than the initial thickness TW. The device thickness TD may be 1 μm or thicker and 150 μm or thinner.

The device thickness TD may have a value in at least one range among a range of 1 μm or thicker and 25 μm or thinner, a range of 25 μm or thicker and 50 μm or thinner, a range of 50 μm or thicker and 75 μm or thinner, a range of 75 μm or thicker and 100 μm or thinner, a range of 100 μm or thicker and 125 μm or thinner, and a range of 125 μm or thicker and 150 μm or thinner. The device thickness TD may be 10 μm or thicker and 120 μm or thinner. Preferably, the device thickness TD is 100 μm or thinner. It is particularly preferable that the device thickness TD is 60 μm or thinner.

The epitaxial layer 12 has an epi thickness TE that is thinner than the initial thickness TW of the wafer body 11. The epi thickness TE may be thinner than the device thickness TD, or may be thicker than the device thickness TD.

The epi thickness TE may be 1 μm or thicker and 30 μm or thinner. The epi thickness TE may have a value in at least one range among a range of 1 μm or thicker and 5 μm or thinner, a range of 5 μm or thicker and 10 μm or thinner, a range of 10 μm or thicker and 15 μm or thinner, a range of 15 μm or thicker and 20 μm or thinner, a range of 20 μm or thicker and 25 μm or thinner, and a range of 25 μm or thicker and 30 μm or thinner. The epi thickness TE may be 3 μm or thicker and 20 μm or thinner. Preferably, the epi thickness TE is 5 μm or thicker and 15 μm or thinner.

The initial thickness of the wafer 2 is a value (=TW+TE) obtained by adding the epi thickness TE of the epitaxial layer 12 to the initial thickness TW of the wafer body 11. The device thickness of the wafer 2 is a value (=TD+TE) obtained by adding the epi thickness TE of the epitaxial layer 12 to the device thickness TD of the wafer body 11. Hereinafter, the initial thickness of the wafer 2 is represented as “initial thickness (TW+TE),” and the device thickness of the wafer 2 is represented as “device thickness (TD+TE).”

The wafer structure 1 includes a plurality of device regions 15 and a plurality of intended cutting lines 16 formed on the wafer 2. For example, the plurality of device regions 15 and the plurality of intended cutting lines 16 are defined by alignment marks or the like formed in the first surface 3 (for example, the epitaxial layer 12).

Each of the plurality of device regions 15 is made of a region corresponding to the semiconductor device SD, and is cut out as a plurality of semiconductor devices SD in a dicing step. The plurality of device regions 15 are arranged in an orderly manner (for example, in a matrix shape) along the a-axis direction and the m-axis direction. Each of the plurality of device regions 15 is defined in a quadrangular shape in a plan view.

The plurality of device regions 15 are formed in an inner portion of the first surface 3 from the first bevel portion 8 through an exclusion region 17. The exclusion region 17 is an exclusive region in which the device region 15 is not formed, and is provided over the entire periphery of the peripheral edge portion of the first surface 3 starting from a proximal end portion of the first bevel portion 8 in the peripheral edge portion of the first surface 3. A width of the exclusion region 17 may be 0.1 mm or wider and 2 mm or narrower. The plurality of intended cutting lines 16 extend in a lattice shape along the a-axis direction and the m-axis direction, and define the plurality of device regions 15.

The wafer structure 1 includes a plurality of device structures 18 that are respectively formed in the plurality of device regions 15 on the first surface 3. Each of the device structures 18 is formed at an interval inwardly from a peripheral edge of each of the device regions 15. Each of the device structures 18 may include at least one of a switching device, a rectifying device, and a passive device.

The switching device may include at least one among a metal insulator semiconductor field effect transistor (MISFET), a bipolar junction transistor (BJT), an insulated gate bipolar junction transistor (IGBT), and a junction field effect transistor (JFET). The rectifying device may include at least one among a pn-junction diode, a pin-junction diode, a Zener diode, a Schottky barrier diode, and a fast recovery diode. The passive device may include at least one among a resistor, a capacitor, an inductor, and a fuse.

Each of the device structures 18 may include a circuit network (for example, an integrated circuit such as an LSI) in which at least two among the switching device, the rectifying device, and the passive device are combined. In this embodiment, each of the device structures 18 includes a MISFET structure as an example of a transistor structure.

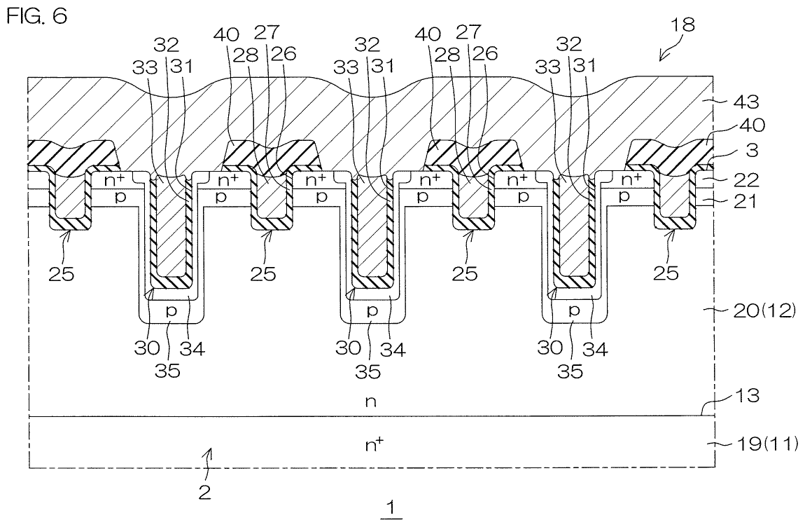

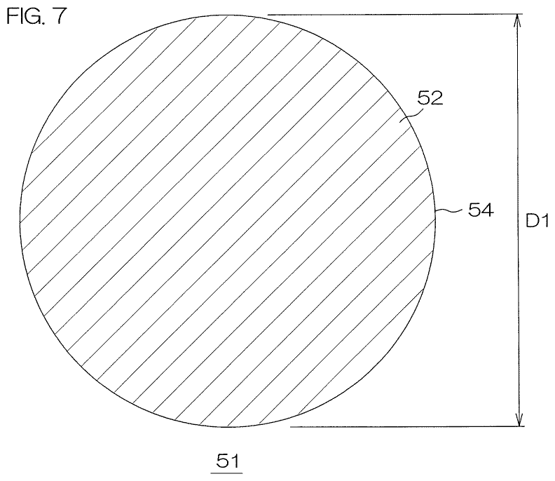

Hereinafter, an example of the device structure 18 will be described. FIG. 5 is a plan view of a main portion illustrating an example of the device structure 18. FIG. 6 is a cross-sectional view taken along line VI-VI illustrated in FIG. 5. Since the structures of the plurality of device regions 15 (device structures 18) are the same, the structure of one device region 15 (device structure 18) will be described below.

Referring to FIG. 5 and FIG. 6, the wafer structure 1 includes an n-type first semiconductor region 19 that is formed in a region (a surface layer portion) on the second surface 4 side in an inner portion of the wafer 2. The first semiconductor region 19 may be referred to as a “drain region.” The first semiconductor region 19 is formed in the inner portion of the wafer body 11, and extends in a layer shape along the second surface 4. In this embodiment, the first semiconductor region 19 is formed in the entire region of the wafer body 11, and is exposed from the second surface 4 and the peripheral end surface 5. In this embodiment, the n-type wafer body 11 is adopted, and the first semiconductor region 19 is formed using the n-type wafer body 11.

The wafer structure 1 includes an n-type second semiconductor region 20 that is formed in a region (a surface layer portion) on the first surface 3 side in the inner portion of the wafer 2.

The second semiconductor region 20 may be referred to as a “drift region.” The second semiconductor region 20 has an n-type impurity concentration lower than an n-type impurity concentration of the first semiconductor region 19.

The second semiconductor region 20 is formed in an inner portion of the epitaxial layer 12, and extends in a layer shape along the first surface 3. The second semiconductor region 20 is electrically connected to the first semiconductor region 19 in a lamination direction. In this embodiment, the second semiconductor region 20 is formed in the entire region of the epitaxial layer 12, and is exposed from the first surface 3 and the peripheral end surface 5. In this embodiment, the n-type epitaxial layer 12 is adopted, and the second semiconductor region 20 is formed using the n-type epitaxial layer 12.

The wafer structure 1 includes a p-type body region 21 that is formed in the surface layer portion of the first surface 3. The body region 21 is formed in a surface layer portion of the second semiconductor region 20 (that is, the epitaxial layer 12). The body region 21 is formed at an interval from a bottom portion of the second semiconductor region 20 toward the first surface 3 side, and opposes the first semiconductor region 19 (that is, the wafer body 11) with a portion of the second semiconductor region 20 interposed therebetween.

The wafer structure 1 includes an n-type source region 22 that is formed in a surface layer portion of the body region 21. The source region 22 has an n-type impurity concentration higher than the n-type impurity concentration of the second semiconductor region 20. The source region 22 forms a channel having a MISFET structure with the second semiconductor region 20 in the body region 21.

The wafer structure 1 includes a plurality of gate structures 25 of trench-electrode-types formed in the first surface 3. The plurality of gate structures 25 control inversion and non-inversion of the channel. The plurality of gate structures 25 are arranged at intervals in the m-axis direction, and respectively extend in a band shape in the a-axis direction. As a matter of course, the plurality of gate structures 25 may be arranged at intervals in the a-axis direction, and may respectively extend in a band shape in the m-axis direction. The plurality of gate structures 25 penetrate the body region 21 and the source region 22, and are formed at an interval from the bottom portion of the second semiconductor region 20 toward the first surface 3 side.

Each of the gate structures 25 includes a first trench 26, a first insulating film 27, and a first embedded electrode 28. The first trench 26 is formed in the first surface 3. The first insulating film 27 covers a wall surface of the first trench 26. The first embedded electrode 28 is embedded in the first trench 26 across the first insulating film 27.

The wafer structure 1 includes a plurality of source structures 30 of trench-electrode-types formed in the first surface 3. The presence or absence of the source structures 30 is arbitrary, and the wafer structure I does not necessarily include the source structures 30. Each of the plurality of source structures 30 extends in a band shape in the a-axis direction in regions between two adjacent gate structures 25. As a matter of course, each of the plurality of source structures 30 may extend in a band shape in the m-axis direction according to the arrangement of the plurality of gate structures 25.

The plurality of source structures 30 penetrate the body region 21 and the source region 22, and are formed at an interval from the bottom portion of the second semiconductor region 20 toward the first surface 3 side. The plurality of source structures 30 are formed to be deeper than the gate structures 25. The plurality of source structures 30 may have a depth that is substantially equal to a depth of the gate structures 25.

Each of the source structures 30 includes a second trench 31, a second insulating film 32, and a second embedded electrode 33. The second trench 31 is formed in the first surface 3. The second insulating film 32 covers a wall surface of the second trench 31. The second embedded electrode 33 is embedded in the second trench 31 with the second insulating film 32 interposed therebetween.

The wafer structure 1 includes a plurality of p-type contact regions 34 that are respectively formed in regions along the plurality of source structures 30 in the second semiconductor region 20. The plurality of contact regions 34 has a p-type impurity concentration higher than the p-type impurity concentration of the body region 21.

The plurality of contact regions 34 are formed in a one-to-multiple correspondence relationship with respect to the corresponding one of the source structures 30. The plurality of contact regions 34 are formed at intervals along the corresponding source structure 30 in a plan view. Each of the contact regions 34 extends along a side wall and a bottom wall of the corresponding source structure 30, and is electrically connected to the body region 21 in the surface layer portion of the first surface 3.

The wafer structure 1 includes a plurality of p-type well regions 35 that are respectively formed in regions along the plurality of source structures 30 in the second semiconductor region 20. Each of the well regions 35 has a p-type impurity concentration higher than the p-type impurity concentration of the body region 21 and lower than the p-type impurity concentration of the contact region 34.

The plurality of well regions 35 are formed in a one-to-one correspondence relationship with respect to the corresponding one of the source structures 30. The plurality of well regions 35 are formed in a band shape extending along the corresponding one of the source structures 30 in a plan view. Each of the well regions 35 opposes the corresponding source structure 30 across the corresponding one of the plurality of contact regions 34. Each of the well regions 35 extends along the side wall and the bottom wall of the corresponding source structure 30, and is electrically connected to the body region 21 in the surface layer portion of the first surface 3.

The wafer structure 1 includes an interlayer film 40 that has an insulating property and covers the first surface 3. In the entire cross-sectional view illustrated on a lower portion of FIG. 2, the interlayer film 40 is not illustrated for convenience (hereinafter, the same applies to the corresponding accompanying drawings). The interlayer film 40 may include at least one of a silicon oxide film, a silicon nitride film, or a silicon oxynitride film.

The interlayer film 40 is formed over almost the entire region of the first surface 3. The interlayer film 40 includes a portion that covers the first bevel portion 8 in the peripheral edge portion of the first surface 3. The interlayer film 40 collectively covers the plurality of gate structures 25 in each of the device regions 15. The interlayer film 40 may have a thickness of 0.1 μm or thicker and 10 μm or thinner.

The wafer structure 1 includes a gate terminal 41, a gate wiring 42, and a source terminal 43. In the overall cross-sectional view illustrated on the lower portion of FIG. 2, the gate terminal 41, the gate wiring 42, and the source terminal 43 are not illustrated for convenience (hereinafter, the same applies to the corresponding accompanying drawings). The gate terminal 41 is arranged in a region close to a central portion of one side of the device region 15. The gate terminal 41 may be arranged in a corner portion of the device region 15. The gate terminal 41 is formed in a quadrangular shape.

The gate terminal 41 is arranged on the interlayer film 40. The gate terminal 41 may have a laminated structure including a Ti-based metal film and an Al-based metal film. The Ti-based metal film may include one or both of a Ti film and a TiN film. The Al-based metal film may include one or both of an Al film and an Al alloy film. The Al alloy film may include at least one of an AlSi alloy film, an AlCu alloy film, and an AlSiCu alloy film. The gate terminal 41 may have a thickness of 0.5 μm or thicker and 10 μm or thinner.

The gate wiring 42 is drawn from the gate terminal 41 onto the interlayer film 40. The gate wiring 42 includes the same type of conductive material as the conductive material of the gate terminal 41, and may have a thickness substantially equal to the thickness of the gate terminal 41. The gate wiring 42 extends in a band shape along the peripheral edge of the device region 15 such as to intersect (specifically, orthogonal to) end portions of the plurality of gate structures 25. The gate wiring 42 is electrically connected to the plurality of gate structures 25 via one or a plurality of through holes (not illustrated) formed on the interlayer film 40.

The source terminal 43 is arranged on the interlayer film 40 in the device region 15. The source terminal 43 may include the same type of conductive material as the conductive material of the gate terminal 41, and may have a thickness substantially equal to the thickness of the gate terminal 41. The source terminal 43 is arranged on the interlayer film 40 at an interval from the gate terminal 41 and the gate wiring 42.

The source terminal 43 is formed in a polygonal shape having a recess portion that is recessed along the gate terminal 41. The source terminal 43 may be formed in a quadrangular shape. The source terminal 43 is electrically connected to the body region 21, the source region 22, and the plurality of source structures 30 via the plurality of through holes formed on the interlayer film 40 (refer to FIG. 6).

The wafer structure 1 includes an organic film 45 of an insulating property that covers the first surface 3. The organic film 45 is formed on the interlayer film 40, and covers the first surface 3 across the interlayer film 40. The organic film 45 covers the inner portion of the first surface 3 in a film shape. Specifically, the organic film 45 selectively covers a region of the first surface 3 that is located inwardly from the exclusion region 17. The organic film 45 selectively covers the gate terminal 41 and the source terminal 43 on the interlayer film 40, and covers the entire region of the gate wiring 42. Preferably, the organic film 45 is thicker than the gate terminal 41 (source terminal 43).

The organic film 45 may include at least one of a photosensitive resin film or a thermosetting resin film. The organic film 45 may have a single layer structure including a photosensitive resin film. The organic film 45 may have a laminated structure including a photosensitive resin film and a thermosetting resin film laminated in this order from the wafer 2 side.

The photosensitive resin film may be a negative type or a positive type. The photosensitive resin film may include at least one of a polyimide film, a polyamide film, or a polybenzoxazole film. The photosensitive resin film may have a thickness of 1 μm or thicker and 50 μm or thinner. In this case, the thickness of the photosensitive resin film may have a value in at least one range among a range of 1 μm or thicker and 10 μm or thinner, a range of 10 μm or thicker and 20 μm or thinner, a range of 20 μm or thicker and 30 μm or thinner, a range of 30 μm or thicker and 40 μm or thinner, and a range of 40 μm or thicker and 50 μm or thinner.

The thermosetting resin film may include a matrix resin (for example, an epoxy resin) and a plurality of fillers. The thermosetting resin film may have a thickness of 10 μm or thicker and 300 μm or thinner. In this case, the thickness of the thermosetting resin film may have a value in at least one range among a range of 10 μm or thicker and 50 μm or thinner, a range of 50 μm or thicker and 100 μm or thinner, a range of 150 μm or thicker and 200 μm or thinner, a range of 200μm or thicker and 250 μm or thinner, and a range of 250 μm or thicker and 300 μm or thinner.

Although not specifically illustrated, the wafer structure 1 may include an inorganic film that has an insulating property and is interposed between the interlayer film 40 and the organic film 45. The inorganic film may be referred to as a “passivation film.” The inorganic film is formed as an uppermost insulating film of the interlayer film 40. For example, the inorganic film may include at least one of a silicon nitride film, a silicon oxynitride film, or a silicon oxide film.

The inorganic film selectively covers the gate terminal 41, the source terminal 43, and the gate wiring 42. The inorganic film may include a portion interposed between the gate terminal 41 and the organic film 45. The inorganic film may have a portion interposed between the source terminal 43 and the organic film 45. The inorganic film may include a portion interposed between the gate wiring 42 and the organic film 45.

The wafer structure 1 includes a gate pad opening 46, a source pad opening 47, and a street opening 48 that are formed in the organic film 45. In the overall cross-sectional view illustrated on the lower portion of FIG. 2, the gate pad opening 46, the source pad opening 47, and the street opening 48 are not illustrated for convenience (hereinafter, the same applies to the corresponding accompanying drawings).

The gate pad opening 46 exposes an inner portion of the gate terminal 41. The source pad opening 47 exposes an inner portion of the source terminal 43. The street opening 48 is formed in a lattice shape along the plurality of intended cutting lines 16, and exposes one or both of the first surface 3 and the interlayer film 40.

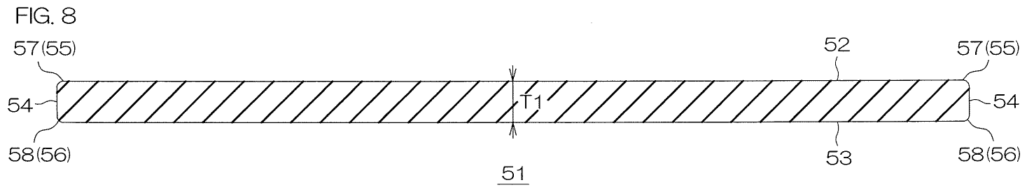

FIG. 7 is a plan view illustrating a first supporting member 51 (first member) used for manufacturing the semiconductor device SD. FIG. 8 is a cross-sectional view illustrating the first supporting member 51. The first supporting member 51 is a robust plate-shaped member that supports the wafer structure 1 from the first surface 3 side of the wafer 2 during the manufacturing step. The first supporting member 51 may be referred to as a “first plate-shaped member,” a “first supporting plate,” or the like.

The first supporting member 51 is formed in a flat disk shape. As a matter of course, the first supporting member 51 may be formed in a flat rectangular parallelepiped shape. The first supporting member 51 may be made of an inorganic plate-shaped member or an organic plate-shaped member. Preferably, the first supporting member 51 is made of a transparent material or a semi-transparent material, and has a light-transmitting property.

The first supporting member 51 includes at least one of glass, ceramic, silicon, silicon carbide, carbon, sapphire, gallium nitride, gallium oxide, resin, or metal (for example, stainless steel, aluminum, or the like). Preferably, the first supporting member 51 is made of glass.

The first supporting member 51 has a first plate surface 52 on one side, a second plate surface 53 on the other side, and peripheral end plate surface 54 that connects the first plate surface 52 and the second plate surface 53. The first plate surface 52 is a support surface that supports the wafer structure 1, and extends to be flat in the horizontal direction. The second plate surface 53 is a non-support surface, and extends to be flat in the horizontal direction. That is, the second plate surface 53 extends to be substantially parallel to the first plate surface 52. The peripheral end plate surface 54 extends in the vertical direction between the first plate surface 52 and the second plate surface 53.

The first supporting member 51 includes a first plate corner portion 55 and a second plate corner portion 56. The first plate corner portion 55 is a connection portion between the first plate surface 52 and the peripheral end plate surface 54. The second plate corner portion 56 is a connection portion between the second plate surface 53 and the peripheral end plate surface 54. In this embodiment, the first supporting member 51 includes a first chamfered portion 57 and a second chamfered portion 58.

The first chamfered portion 57 is formed in the first plate corner portion 55. The first chamfered portion 57 is formed of an inclined portion (inclined surface) inclined obliquely downward from the first plate surface 52 toward the second plate surface 53 side in a peripheral edge portion of the first plate surface 52. The first chamfered portion 57 may extend in a straight line shape in a cross-sectional view. The first chamfered portion 57 may extend in an arc shape (circular arc shape) in a cross-sectional view.

The second chamfered portion 58 is formed in the second plate corner portion 56. The second chamfered portion 58 is formed of an inclined portion (inclined surface) inclined obliquely downward from the second plate surface 53 toward the first plate surface 52 side in a peripheral edge portion of the second plate surface 53. The second chamfered portion 58 may extend in a straight line shape in a cross-sectional view. The second chamfered portion 58 may extend in an arc shape (circular arc shape) in a cross-sectional view.

The presence or absence of the first chamfered portion 57 and the second chamfered portion 58 is arbitrary. Therefore, the first supporting member 51 that includes the first chamfered portion 57 and does not include the second chamfered portion 58 may be adopted. In this case, the second plate corner portion 56 connects the second plate surface 53 and the peripheral end plate surface 54 in a substantially perpendicular manner. Also, the first supporting member 51 that includes the second chamfered portion 58 and does not include the first chamfered portion 57 may be adopted. In this case, the first plate corner portion 55 connects the first plate surface 52 and the peripheral end plate surface 54 in a substantially perpendicular manner. As a matter of course, the first supporting member 51 that does not include both of the first chamfered portion 57 and the second chamfered portion 58 may be adopted.

Preferably, the first supporting member 51 has a first diameter D1 equal to or larger than the wafer diameter DW. The first diameter D1 is defined by a length (that is, a diameter) of a chord passing through a center of the first supporting member 51. It is particularly preferable that the first diameter D1 is larger than the wafer diameter DW. Preferably, a difference value (D1−DW) between the wafer diameter DW and the first diameter D1 falls within a range equal to or larger than 0.1 mm and smaller than 10 mm.

The difference value (D1−DW) may have a value in at least one range among a range of 0.1 mm or larger and 0.5 mm or smaller, a range of 0.5 mm or larger and 1 mm or smaller, a range of 1 mm or larger and 1.5 mm or smaller, a range of 1.5 mm or larger and 2 mm or smaller, a range of 2 mm or larger and 2.5 mm or smaller, a range of 2.5 mm or larger and 3 mm or smaller, a range of 3 mm or larger and 3.5 mm or smaller, a range of 3.5 mm or larger and 4 mm or smaller, a range of 4 mm or larger and 4.5 mm or smaller, a range of 4.5 mm or larger and 5 mm or smaller, a range of 5 mm or larger and 6 mm or smaller, a range of 6 mm or larger and 7 mm or smaller, a range of 7 mm or larger and 8 mm or smaller, a range of 8 mm or larger and 9 mm or smaller, and a range equal to or larger than 9 mm and smaller than 10 mm. Preferably, the difference value (D1−DW) is 1 mm or larger.

In a case where the first diameter D1 is larger than the wafer diameter DW, the first supporting member 51 supports the wafer 2 such as to protrude outwardly from the peripheral end surface 5 of the wafer 2. In this case, the first supporting member 51 supports the wafer 2 with the difference value (D1−DW) as a protrusion width, and provides protection for the wafer 2 (particularly, the peripheral end surface 5).

The first supporting member 51 has a first thickness T1 thicker than the epi thickness TE of the epitaxial layer 12. Preferably, the first thickness T1 is thicker than the device thickness TD of the wafer body 11. Preferably, the first thickness T1 is equal to or thicker than the device thickness (TD+TE) of the wafer 2. Preferably, the first thickness T1 is thicker than the device thickness (TD+TE). Preferably, the first thickness T1 is equal to or thicker than the initial thickness (TW+TE) of the wafer 2. Preferably, the first thickness T1 is thicker than the initial thickness (TW+TE).

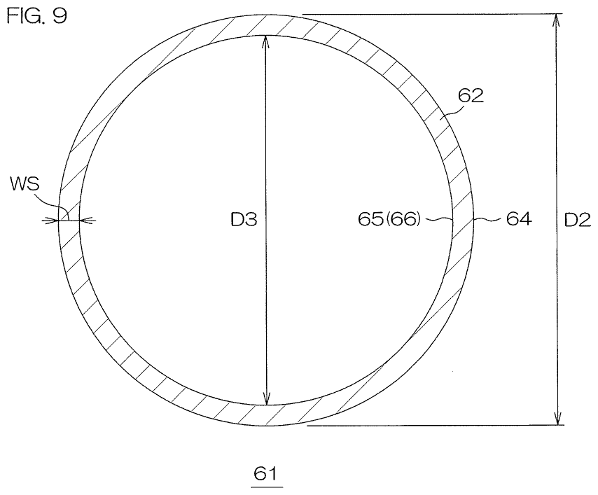

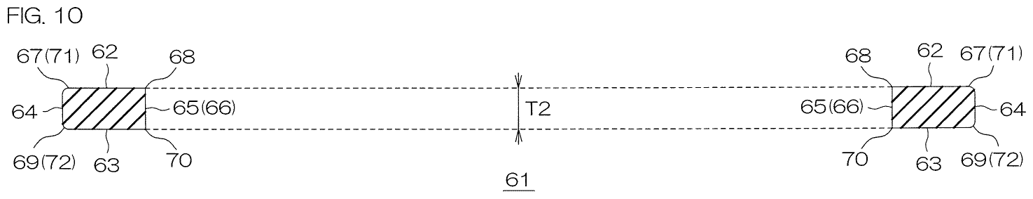

FIG. 9 is a plan view illustrating a second supporting member 61 (second member) used for manufacturing the semiconductor device SD. FIG. 10 is a cross-sectional view illustrating the second supporting member 61. The second supporting member 61 is a robust plate-shaped member that supports the wafer structure 1 from the second surface 4 side of the wafer 2 during the manufacturing step. The second supporting member 61 may be referred to as a “second plate-shaped member,” a “second supporting plate,” or the like.

The second supporting member 61 is formed in a flat band plate shape with ends or a flat band plate shape without an end and is configured to expose the inner portion of the second surface 4 of the wafer 2 and cover the peripheral edge portion of the second surface 4 of the wafer 2. The second supporting member 61 may be formed in an arc plate shape, a circular arc plate shape, or an annular plate shape extending along the outer shape (peripheral end surface 5) of the wafer 2. In this embodiment, the second supporting member 61 is formed in an annular plate shape. The second supporting member 61 may be made of an inorganic plate-shaped member or an organic plate-shaped member. Preferably, the second supporting member 61 is made of a transparent material or a semi-transparent material, and has a light-transmitting property.

The second supporting member 61 includes at least one of glass, ceramic, silicon, silicon carbide, carbon, sapphire, gallium nitride, gallium oxide, resin, or metal (for example, stainless steel, aluminum, or the like). The second supporting member 61 may be made of the same type of plate material as the plate material of the first supporting member 51. The plate material of the second supporting member 61 may be different from the plate material of the first supporting member 51. Preferably, the second supporting member 61 is made of glass.

The second supporting member 61 includes a first plate surface 62 on one side, a second plate surface 63 on the other side, an outer end surface 64 that connects the first plate surface 62 and the second plate surface 63, and an inner end surface 65 that connects the first plate surface 62 and the second plate surface 63. The first plate surface 62 is a support surface that supports the wafer structure 1, and extends in a flat annular shape in the horizontal direction. The second plate surface 63 is a non-support surface, and extends in a flat annular shape in the horizontal direction. That is, the second plate surface 63 extends to be substantially parallel to the first plate surface 62.

The outer end surface 64 is formed in a circular shape in a plan view, and extends in the vertical direction between the first plate surface 62 and the second plate surface 63. The inner end surface 65 is formed in a circular shape in a plan view, and extends in the vertical direction between the first plate surface 62 and the second plate surface 63. The inner end surface 65 extends to be substantially parallel to the outer end surface 64. The inner end surface 65 defines an opening 66 having a circular shape in a plan view.

The first plate surface 62 includes a first outer corner portion 67 on the outer end surface 64 side and a first inner corner portion 68 on the inner end surface 65 side. The first outer corner portion 67 is a connection portion between the first plate surface 62 and the outer end surface 64.

The first inner corner portion 68 is a connection portion between the first plate surface 62 and the inner end surface 65. The second plate surface 63 includes a second outer corner portion 69 on the outer end surface 64 side and a second inner corner portion 70 on the inner end surface 65 side. The second outer corner portion 69 is a connection portion between the second plate surface 63 and the outer end surface 64. The second inner corner portion 70 is a connection portion between the second plate surface 63 and the inner end surface 65.

The second supporting member 61 includes a first chamfered portion 71 and a second chamfered portion 72. The first chamfered portion 71 is formed in the first outer corner portion 67. The first chamfered portion 71 is formed of an inclined portion (inclined surface) inclined obliquely downward from the first plate surface 62 toward the second plate surface 63 side in a peripheral edge portion of the first plate surface 62 on the outer end surface 64 side. The first chamfered portion 71 may extend in a straight line shape in a cross-sectional view. The first chamfered portion 71 may extend in an arc shape (circular arc shape) in a cross-sectional view.

The second chamfered portion 72 is formed in the second outer corner portion 69. The second chamfered portion 72 is formed of an inclined portion (inclined surface) inclined obliquely downward from the second plate surface 63 toward the first plate surface 62 side in a peripheral edge portion of the second plate surface 63 on the outer end surface 64 side. The second chamfered portion 72 may extend in a straight line shape in a cross-sectional view. The second chamfered portion 72 may extend in an arc shape (circular arc shape) in a cross-sectional view.

The presence or absence of the first chamfered portion 71 and the second chamfered portion 72 is arbitrary. Therefore, the second supporting member 61 that includes the first chamfered portion 71 and does not include the second chamfered portion 72 may be adopted. In this case, the second outer corner portion 69 connects the second plate surface 63 and the outer end surface 64 in a substantially perpendicular manner. Also, the second supporting member 61 that includes the second chamfered portion 72 and does not include the first chamfered portion 71 may be adopted. As a matter of course, the second supporting member 61 that does not include both of the first chamfered portion 71 and the second chamfered portion 72 may be adopted. In this case, the first outer corner portion 67 connects the first plate surface 62 and the outer end surface 64 in a substantially perpendicular manner.

In this embodiment, the first inner corner portion 68 does not include a chamfered portion, and is angular. As a matter of course, the first inner corner portion 68 may include a first chamfered portion 71 similarly to the first outer corner portion 67. That is, the first inner corner portion 68 may include an inclined portion (inclined surface) inclined obliquely downward from the first plate surface 62 toward the second plate surface 63 side in the peripheral edge portion of the first plate surface 62 on the inner end surface 65 side.

In this embodiment, the second inner corner portion 70 does not include a chamfered portion, and is angular. As a matter of course, the second inner corner portion 70 may include a second chamfered portion 72 similarly to the second outer corner portion 69. That is, the second inner corner portion 70 may include an inclined portion (inclined surface) inclined obliquely downward from the second plate surface 63 toward the first plate surface 62 side in the peripheral edge portion of the second plate surface 63 on the inner end surface 65 side.

The second supporting member 61 has a support width WS. The support width WS is a distance (width) between the outer end surface 64 and the inner end surface 65. The support width WS may be 1 mm or wider and 10 mm or narrower. The support width WS may have a value in at least one range among a range of 1 mm or wider and 2 mm or narrower, a range of 2 mm or wider and 4 mm or narrower, a range of 4 mm or wider and 6 mm or narrower, a range of 6 mm or wider and 8 mm or narrower, and a range of 8 mm or wider and 10 mm or narrower. The support width WS may be 2 mm or wider and 5 mm or narrower. Preferably, the support width WS is 2.5 mm or wider and 4 mm or narrower.

The second supporting member 61 has, as an outer diameter, a second diameter D2 equal to or larger than the wafer diameter DW. The second diameter D2 is larger than the wafer diameter DW. The second diameter D2 is defined by a length (that is, a diameter) of a chord passing through a center (annular center) of the second supporting member 61 when the outer end surface 64 is set as a reference. The second diameter D2 is appropriately adjusted according to the wafer diameter DW.

The second supporting member 61 has an inner diameter D3 smaller than the wafer diameter DW. The inner diameter D3 is defined by a length (that is, a diameter) of a chord passing through the center (annular center) of the second supporting member 61 when the inner end surface 65 is set as a reference. The inner diameter D3 is a value (D2−WS) obtained by subtracting the support width WS from the second diameter D2. Preferably, a difference value (D2−DW) falls within a range equal to or larger than 0.1 mm and smaller than 10 mm.

The difference value (D2−DW) may have a value in at least one range among a range of 0.1 mm or larger and 0.5 mm or smaller, a range of 0.5 mm or larger and 1 mm or smaller, a range of 1 mm or larger and 1.5 mm or smaller, a range of 1.5 mm or larger and 2 mm or smaller, a range of 2 mm or larger and 2.5 mm or smaller, a range of 2.5 mm or larger and 3 mm or smaller, a range of 3 mm or larger and 3.5 mm or smaller, a range of 3.5 mm or larger and 4 mm or smaller, a range of 4 mm or larger and 4.5 mm or smaller, a range of 4.5 mm or larger and 5 mm or smaller, a range of 5 mm or larger and 6 mm or smaller, a range of 6 mm or larger and 7 mm or smaller, a range of 7 mm or larger and 8 mm or smaller, a range of 8 mm or larger and 9 mm or smaller, and a range equal to or larger than 9 mm and smaller than 10 mm. Preferably, the difference value (D2−DW) is 1 mm or larger.

In a case where the second diameter D2 is larger than the wafer diameter DW, the second supporting member 61 supports the wafer 2 such as to protrude outwardly from the peripheral end surface 5 of the wafer 2. In this case, the second supporting member 61 supports the wafer 2 with the difference value (D2−DW) as a protrusion width, and provides protection for the wafer 2 (particularly, the peripheral end surface 5). The second diameter D2 may be different from the first diameter D1 of the first supporting member 51. The second diameter D2 may be larger than the first diameter D1, or may be smaller than the first diameter D1. Preferably, the second diameter D2 is substantially equal to the first diameter D1.

The second supporting member 61 has a second thickness T2 thicker than the epi thickness TE of the epitaxial layer 12. Preferably, the second thickness T2 is thicker than the device thickness TD of the wafer body 11. Preferably, the first thickness T1 is equal to or thicker than the device thickness (TD+TE) of the wafer 2. Preferably, the second thickness T2 is thicker than the device thickness (TD+TE).

Preferably, the second thickness T2 is equal to or thicker than the initial thickness (TW+TE) of the wafer 2. Preferably, the second thickness T2 is thicker than the initial thickness (TW+TE). The second thickness T2 may be different from the first thickness T1 of the first supporting member 51. The second thickness T2 may be thicker than the first thickness T1, or may be thinner than the first thickness T1. The second thickness T2 may be substantially equal to the first thickness T1.

Next, a manufacturing method for the semiconductor device SD using the wafer structure 1, the first supporting member 51, and the second supporting member 61 will be described.

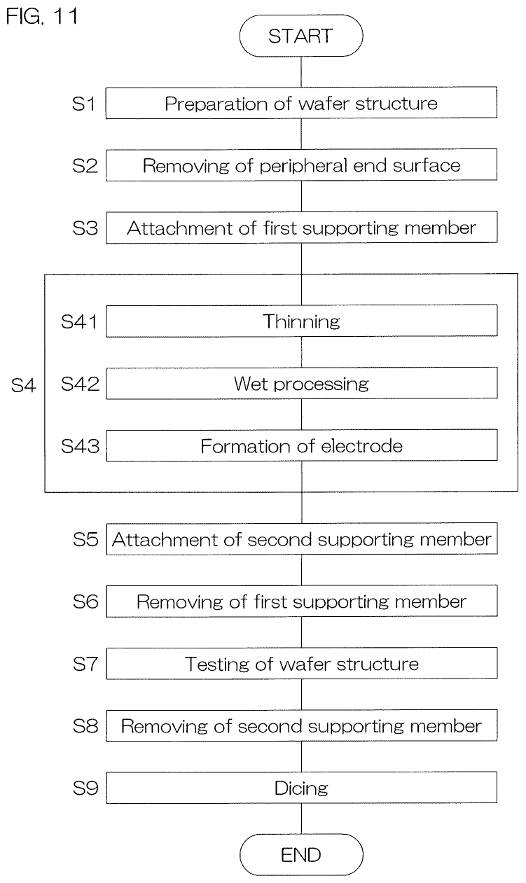

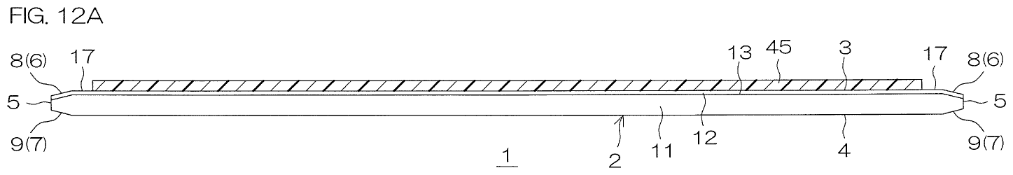

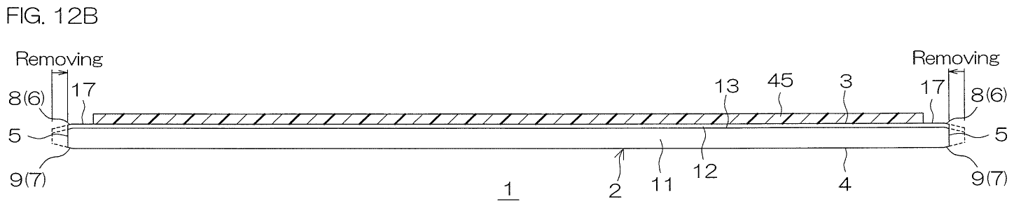

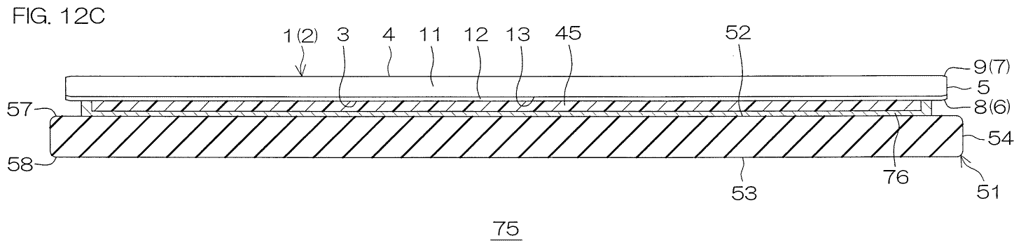

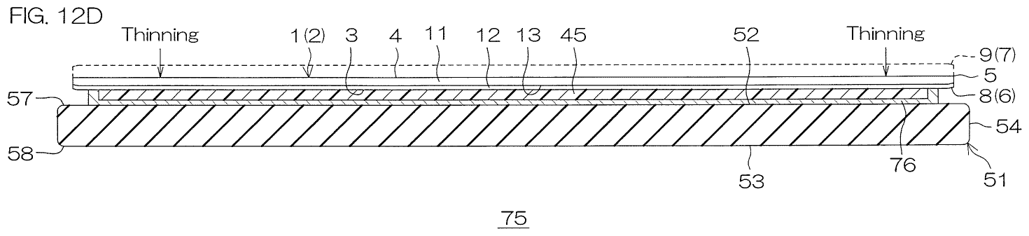

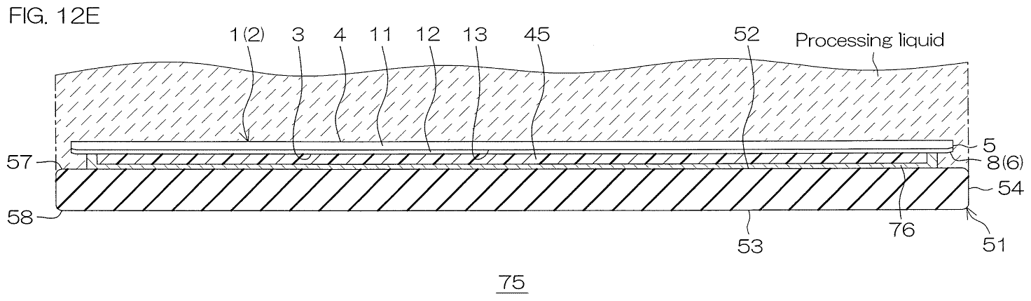

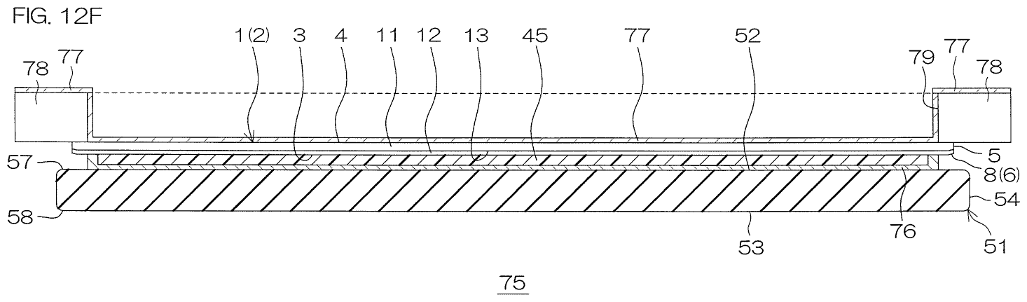

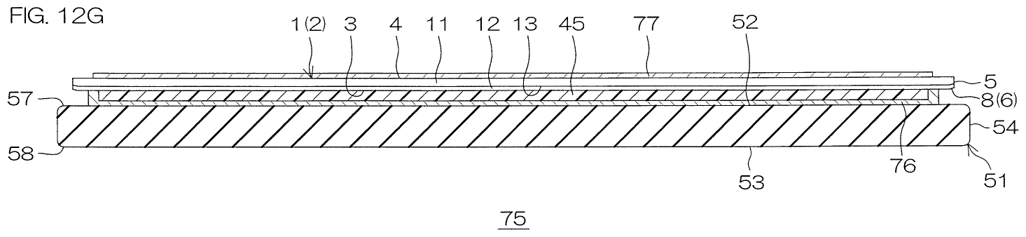

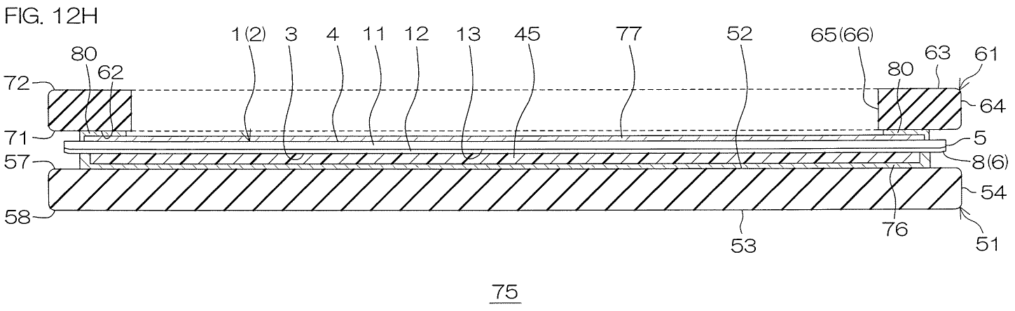

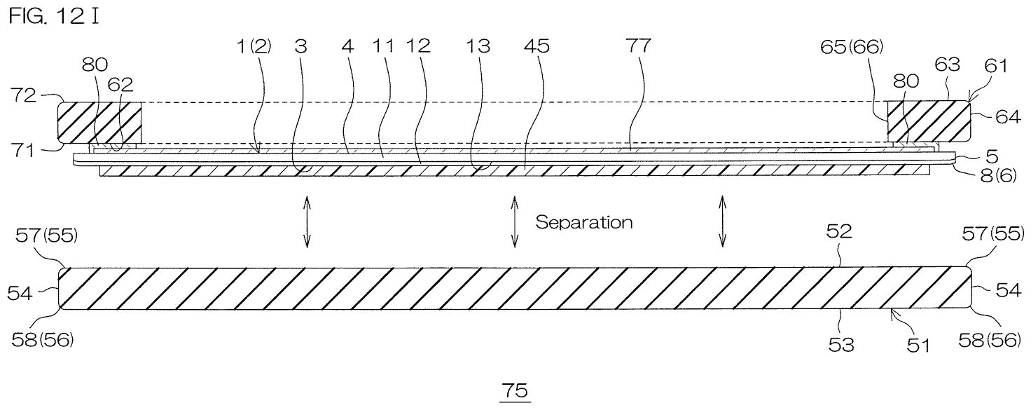

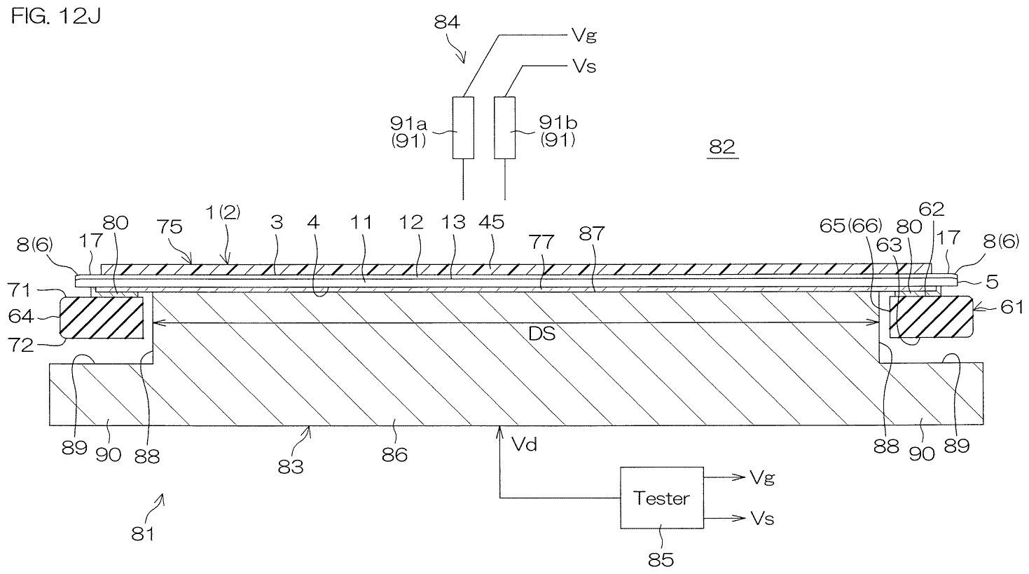

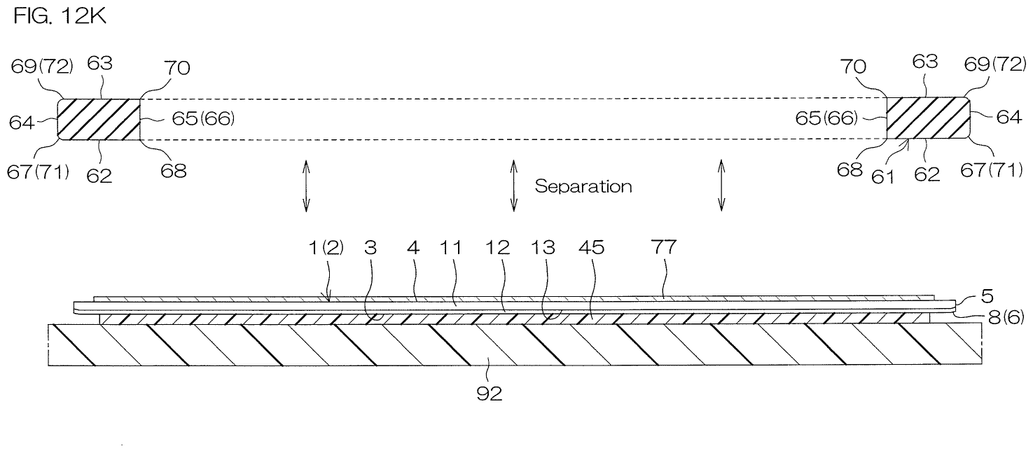

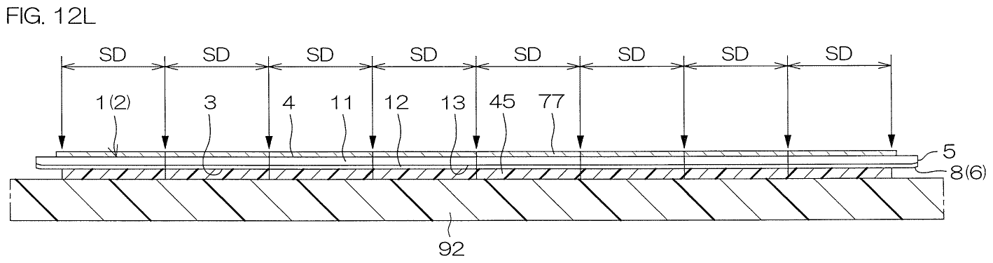

Specifically, the manufacturing method for the semiconductor device SD is a manufacturing method for an SiC semiconductor device as an example of a wide bandgap semiconductor device. FIG. 11 is a flowchart illustrating an example of the manufacturing method for the semiconductor device SD. FIG. 12A to FIG. 12L are cross-sectional views illustrating an example of the manufacturing method for the semiconductor device SD according to FIG. 11.

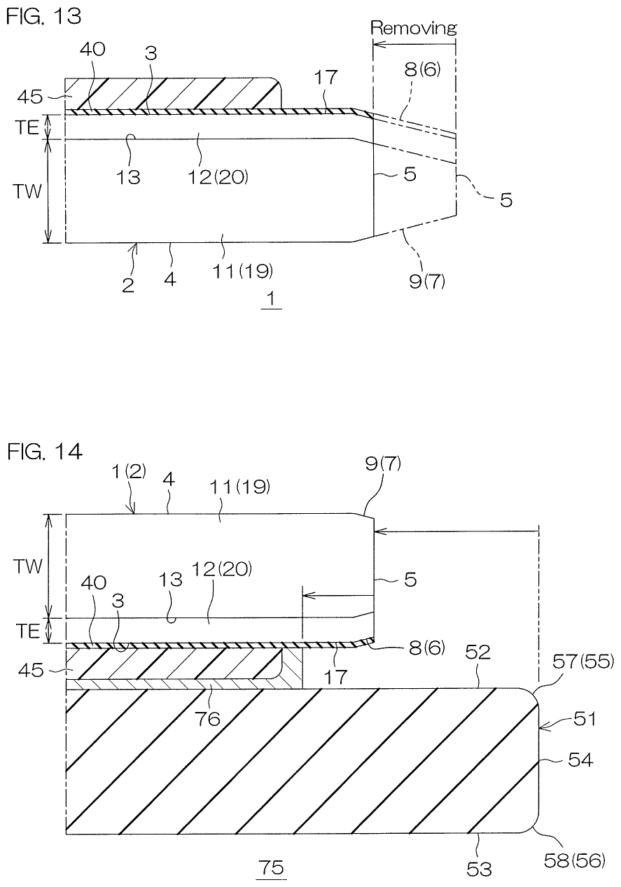

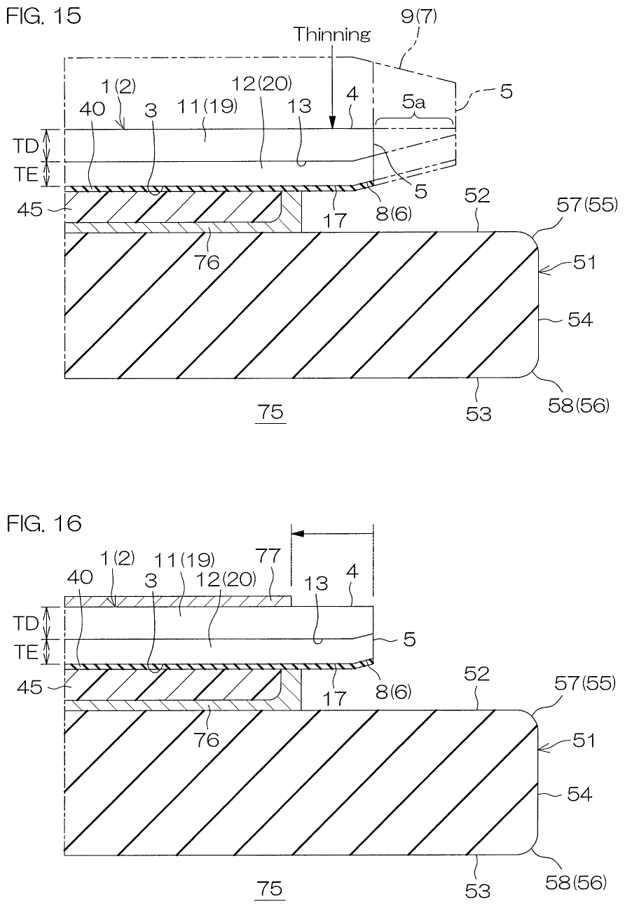

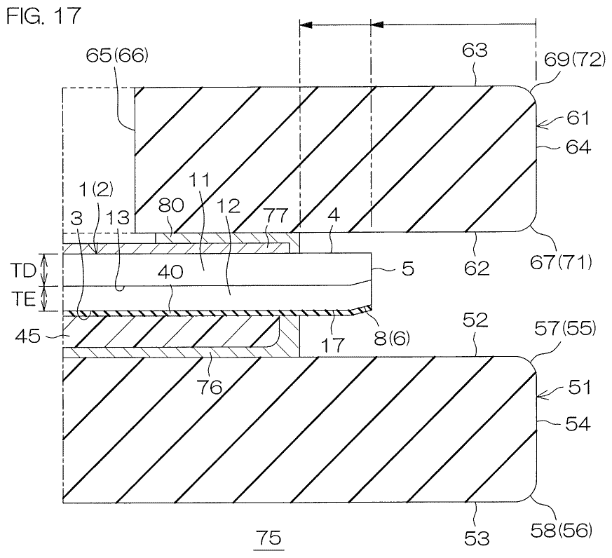

FIG. 13 is an enlarged cross-sectional view illustrating a step of removing the peripheral end surface 5 (FIG. 12B). FIG. 14 is an enlarged cross-sectional view illustrating a step of supporting the first supporting member 51 (FIG. 12C). FIG. 15 is an enlarged cross-sectional view illustrating a step of thinning the wafer structure 1 (FIG. 12D). FIG. 16 is an enlarged cross-sectional view illustrating a forming step of an electrode 77 (FIG. 12G). FIG. 17 is an enlarged cross-sectional view illustrating a step of supporting the second supporting member 61 (FIG. 12H).

First, referring to FIG. 12A, the above-described wafer structure 1 (refer to FIG. 1 and the like) is prepared (step SI in FIG. 11). Next, referring to FIG. 12B, the peripheral end surface 5 of the wafer 2 is partially removed, and the diameter of the wafer 2 is reduced (step S2 in FIG. 11). In this step, the wafer body 11, the epitaxial layer 12, and the interlayer film 40 are simultaneously removed from the peripheral end surface 5 side. In this step, preferably, a region that is located outwardly from the peripheral edge of the organic film 45 in the peripheral edge portion of the wafer 2 is removed. That is, in this step, preferably, the organic film 45 is not removed.

Preferably, the diameter of the wafer 2 is reduced inwardly from the entire periphery. That is, preferably, the peripheral end surface 5 is partially removed over the entire periphery. The peripheral end surface 5 may be removed by either or both of an etching method and a bevel grinding method. The etching method may be either or both of a wet etching method and a dry etching method. In this embodiment, the peripheral end surface 5 is removed by a bevel grinding method, and the peripheral end surface 5 made of a ground surface is formed.

Referring also to FIG. 11, in this step, a part or all of the first bevel portion 8 is removed from the peripheral end surface 5 side, and a part or all of the second bevel portion 9 is removed from the peripheral end surface 5 side. Thereby, a crack or the like caused by an external force or the like against the peripheral end surface 5 (the first bevel portion 8 and the second bevel portion 9) is suppressed. The first bevel portion 8 and the second bevel portion 9 may be removed from the peripheral end surface 5 side at the same timing, or may be removed at different timings.

Preferably, the first bevel portion 8 is removed until the first bevel width WB1 becomes ½ or narrower. Preferably, the second bevel portion 9 is removed until the second bevel width WB2 becomes ½ or narrower. In this embodiment, in order to minimize a reduction in the diameter of the wafer 2, a portion of the first bevel portion 8 and a portion of the second bevel portion 9 remain. In this case, a decrease in the number of the plurality of device regions 15 (device structures 18) (that is, the number of semiconductor devices SD obtained) due to the reduction in the diameter of the wafer 2 is suppressed.

Next, referring to FIG. 12C, the above-described first supporting member 51 is prepared, and is attached to the first surface 3 side of the wafer 2 (step S3 in FIG. 11). That is, the wafer structure 1 is supported by the first supporting member 51 from the first surface 3 side of the wafer 2. Thereby, a wafer support structure 75 including the wafer structure 1 and the first supporting member 51 is formed.

This step may include a step of attaching the wafer 2 to the first supporting member 51 from the first surface 3 side in a state where the first supporting member 51 is fixed. This step may include a step of attaching the first supporting member 51 to the first surface 3 of the wafer 2 in a state where the wafer 2 is fixed. Preferably, the wafer 2 is located on the first plate surface 52 at an interval inwardly from the peripheral end plate surface 54 of the first supporting member 51. The first supporting member 51 opposes the entire region of the first surface 3 of the wafer 2 in the lamination direction, and collectively covers the plurality of device regions 15 (device structures 18).

Referring also to FIG. 14, the first supporting member 51 opposes the first bevel portion 8 in the lamination direction in the peripheral edge portion of the wafer 2. The first supporting member 51 includes a protruding portion that protrudes outward from the peripheral end surface 5 of the wafer 2. The peripheral end plate surface 54 of the first supporting member 51 provides protection for the peripheral end surface 5 (first bevel portion 8) of the wafer 2.

In a case where the first diameter D1 of the first supporting member 51 is smaller than the wafer diameter DW, the peripheral end surface 5 of the wafer 2 is removed until the wafer diameter DW becomes smaller than the first diameter D1 in the diameter reduction step. Therefore, according to the diameter reduction step, the wafer 2 can be reliably located inwardly from the peripheral end plate surface 54. Here, in this case, a removed area of the wafer 2 increases. Therefore, preferably, the first diameter D1 is set in advance to a value substantially equal to the wafer diameter DW or a value larger than the wafer diameter DW.

The first supporting member 51 is adhered to the first surface 3 side of the wafer 2 via a first adhesive member 76. That is, the wafer support structure 75 includes the first adhesive member 76 interposed between the first surface 3 of the wafer 2 and the first plate surface 52 of the first supporting member 51. In this embodiment, the first adhesive member 76 is made of a double-sided adhesive tape having a first peeling condition. The first peeling condition may be one of a thermal peeling type and an ultraviolet peeling type. The thermal peeling type is a peeling condition in which the adhesive force is reduced by heating. On the other hand, the ultraviolet peeling type is a peeling condition in which the adhesive force is reduced by irradiation of ultraviolet rays.

The first adhesive member 76 extends in a film shape along the first surface 3 of the wafer 2 and the first plate surface 52 of the first supporting member 51. In this embodiment, the first adhesive member 76 is interposed between the organic film 45 and the first plate surface 52, and adheres the wafer 2 to the first plate surface 52 via the organic film 45. The first adhesive member 76 may include a portion adhered to the gate terminal 41 via the gate pad opening 46. The first adhesive member 76 may include a portion adhered to the source terminal 43 via the source pad opening 47.

Preferably, the first adhesive member 76 is interposed in the entire region between the organic film 45 and the first plate surface 52. The first adhesive member 76 includes an extending portion that is drawn outwardly from the organic film 45 in the peripheral edge portion of the first plate surface 52. The extending portion of the first adhesive member 76 is adhered to a portion that is exposed from the organic film 45 in the peripheral edge portion of the first surface 3 of the wafer 2.

The term “adhering” mentioned herein includes a form in which the first adhesive member 76 is directly adhered to the first surface 3 of the wafer 2, and also includes a form in which the first adhesive member 76 is adhered to the first surface 3 of the wafer 2 via another structure (for example, an inorganic insulating film such as the interlayer film 40) (hereinafter, the same applies to this specification).

The extending portion of the first adhesive member 76 is formed at an interval inwardly from the peripheral end plate surface 54 of the first supporting member 51, and exposes the peripheral edge portion of the first plate surface 52. The extending portion of the first adhesive member 76 exposes the peripheral end surface 5 of the wafer 2. Specifically, the extending portion of the first adhesive member 76 is formed at an interval inwardly from the peripheral end surface 5 of the wafer 2, and exposes the peripheral edge portion of the first surface 3. Thereby, stress of the first adhesive member 76 on the peripheral edge portion of the first surface 3 is reduced, and a crack starting from the peripheral edge portion of the first surface 3 is suppressed.

The term “exposing” mentioned herein includes a form in which the first adhesive member 76 directly exposes the first surface 3 of the wafer 2, and also includes a form in which the first adhesive member 76 exposes the first surface 3 of the wafer 2 via another structure (for example, an inorganic insulating film such as the interlayer film 40) (hereinafter, the same applies to this specification).

The extending portion of the first adhesive member 76 is formed at an interval inwardly from the first bevel portion 8, and exposes the first bevel portion 8 from the peripheral edge portion of the first surface 3. Thereby, stress of the first adhesive member 76 on the first bevel portion 8 is reduced, and a crack starting from the first bevel portion 8 is suppressed. The extending portion of the first adhesive member 76 forms a gap portion between the peripheral edge portion of the first surface 3 and the peripheral edge portion of the first plate surface 52. A height of the gap portion is substantially equal to the total thickness of the thickness of the organic film 45 and the thickness of the first adhesive member 76, and is extremely low (for example, 1 mm or thinner).

Next, referring to FIG. 12D, a processing step of the wafer 2 is performed in a state where the wafer 2 is supported by the first supporting member 51 (step S4 in FIG. 11). The processing step of the wafer 2 includes a step of thinning the wafer 2 in the state where the wafer 2 is supported by the first supporting member 51 (step S41 in FIG. 11). The thinning step may include at least one of a grinding step of the wafer 2, an etching step of the wafer 2, and a cleaving step of the wafer 2.

In the grinding step, an unnecessary portion of the wafer 2 is removed from the second surface 4 side by a grinding method. The grinding method may include at least one of a mechanical polishing method, a chemical polishing method, or a chemical/mechanical polishing method. In this embodiment, the second surface 4 is ground by one or both of the mechanical polishing method and the chemical/mechanical polishing method. Thereby, the second surface 4 including the ground surface is formed. The grinding step may include a mirror finishing step of the second surface 4. In this case, the second surface 4 is formed of a mirror surface as an example of a ground surface.

In the etching step, an unnecessary portion of the wafer 2 is removed from the second surface 4 side by an etching method. The etching method may be either or both of a wet etching method and a dry etching method. In this step, the second surface 4 that serves as an etched surface is formed. As a matter of course, the thinning step may include a grinding step of the wafer 2 after the etching step.

In the cleaving step of the wafer 2, a plurality of modified layers (damaged layers) along the horizontal direction are formed in the inner portion of the wafer 2 by a laser beam irradiation method, and a cleaving force is applied to the plurality of modified layers. Thereby, the wafer 2 is cleaved in the horizontal direction starting from the plurality of modified layers. For example, the cleaving force may be stress caused by ultrasonic vibration, thermal stress caused by heating and cooling, or the like.

Preferably, the plurality of modified layers are formed in the inner portion of the wafer body 11 at an interval from the epitaxial layer 12. In this step, the second surface 4 that serves as a cleavage surface is formed. As a matter of course, the thinning step may include any one or both of the grinding step of the wafer 2 and the etching step of the wafer 2 after the cleaving step.

The wafer 2 is thinned from the initial thickness (TW+TE) to the device thickness (TD+TE) in the thinning step. The specific value of the device thickness TD (1 μm or thicker and 150 μm or thinner) and the specific value of the epi thickness TE (1 μm or thicker and 30 μm or thinner) are as described above. In this embodiment, the wafer 2 having the initial thickness (TW+TE) of 150 μm or thicker is prepared, and the wafer 2 is thinned until the device thickness (TD+TE) becomes thinner than 150 μm.

Preferably, the device thickness (TD+TE) is 100 μm or thinner. The device thickness (TD+TE) may be equal to or thinner than 100 μm, equal to or thinner than 80 μm, equal to or thinner than 50 μm, equal to or thinner than 40 μm, equal to or thinner than 30 μm, equal to or thinner than 20 μm, or equal to or thinner than 10 μm. The wafer 2 may be removed until the device thickness TD becomes thinner than the epi thickness TE. The wafer 2 may be removed such that the device thickness TD is not equal to or thinner than the epi thickness TE. As a matter of course, the wafer 2 may be removed until the epitaxial layer 12 is exposed. That is, the entire wafer body 11 may be removed (device thickness TD=0 μm).

Referring also to FIG. 15, in this step, a part or all of (in this embodiment, all) of the second bevel portion 9 is removed from the peripheral edge portion of the second surface 4. Thereby, in subsequent steps, a crack caused by the second bevel portion 9 is suppressed. In this step, the second corner portion 7 that is angular is formed in the peripheral edge portion of the second surface 4. That is, the second corner portion 7 is formed to be substantially perpendicular to the peripheral end surface 5.

In this step, since the diameter reduction step of the wafer 2 is performed prior to the thinning step, the peripheral edge portion is suppressed from being sharpened due to the first bevel portion 8 after the thinning step. That is, in a case where the diameter reduction step is not performed, a sharp thin portion 5a (refer to a portion indicated by a broken line in FIG. 15) is formed between the second surface 4 and the first bevel portion 8 after the thinning step. In this regard, in the thinning step after the diameter reduction step, formation of a thin portion 5a is suppressed. Thereby, a crack starting from the peripheral end surface 5 is suppressed.

The reduction in the strength of the wafer 2 due to the thinning is reinforced by the first supporting member 51. Therefore, handling of the wafer structure 1 (wafer support structure 75) after the thinning step is appropriately performed by the first supporting member 51. That is, the wafer 2 that is subjected to the thinning step is inevitably warped (deformed) due to weight of the wafer 2. In this regard, the first supporting member 51 supports the wafer 2 in a horizontally extended state, and suppresses warpage (deformation) and breakage of the wafer 2.

Referring to FIG. 12E, the processing step of the wafer 2 may include a step of performing wet processing on the wafer 2 using a processing liquid in a state where the wafer 2 is supported by the first supporting member 51 after the thinning step (step S42 in FIG. 11).

For example, the processing liquid may be a rinse liquid or a chemical liquid for the second surface 4 (wafer 2), and the wet processing may be cleaning processing of the second surface 4 (wafer 2). For example, the processing liquid may be a chemical liquid such as an etching liquid for the second surface 4 (wafer 2), and the wet processing may be wet etching processing for the second surface 4 (wafer 2). In a case where the processing liquid is a chemical liquid or the like, preferably, the first adhesive member 76 has chemical resistance.

The first supporting member 51 defines a fine gap portion with the wafer 2. Therefore, in this step, the processing liquid is suppressed from entering into the gap portion between the first supporting member 51 and the wafer 2. Also, in this embodiment, the first adhesive member 76 is located inwardly from the peripheral end surface 5 of the wafer 2.

Therefore, the processing liquid is suppressed from entering into an adhesion portion between the wafer 2 and the first adhesive member 76, and the processing liquid is suppressed from entering into an adhesion portion between the first supporting member 51 and the first adhesive member 76. Thereby, peeling of the wafer 2 from the first supporting member 51 is suppressed, and peeling of the first supporting member 51 from the wafer 2 is suppressed. Such a configuration is effective in suppressing a crack caused by peeling of the wafer 2 in the peripheral edge portion of the wafer 2.

Referring to FIG. 12F, the processing step of the wafer 2 includes a step of forming an electrode 77 on the second surface 4 in a state where the wafer 2 is supported by the first supporting member 51 after the thinning step (step S43 in FIG. 11). That is, in this step, the wafer support structure 75 including the electrode 77 is formed. In this embodiment, the forming step of the electrode 77 is performed after the wet processing step. In this embodiment, the electrode 77 is a drain terminal, and is formed by one or both of a sputtering method and a vapor deposition method.

The electrode 77 may have a single layer structure including a single metal film or a laminated structure including a plurality of metal films. For example, the electrode 77 may include at least one of a Ti film, an Ni film, a Pd film, an Au film, an Ag film, or an Al film. The electrode 77 may have a laminated structure in which at least two of a Ti film, an Ni film, a Pd film, an Au film, an Ag film, and an Al film are laminated in an arbitrary order. Preferably, the electrode 77 includes a Ti film that directly covers at least the second surface 4. For example, the electrode 77 may have a laminated structure including a Ti film, an Ni film, a Pd film, and an Au film that are laminated in this order from the second surface 4 side.

The electrode 77 has a thickness thinner than the device thickness (TD+TE) of the wafer 2. The electrode 77 has a thickness thinner than the device thickness TD of the wafer body 11. The electrode 77 has a thickness thinner than the epi thickness TE of the epitaxial layer 12. The thickness (total thickness) of the electrode 77 may be 0.1 μm or thicker and 5 μm or thinner. The thickness (total thickness) of the electrode 77 may have a value in at least one range among a range of 0.1 μm or thicker and 0.5 μm or thinner, a range of 0.5 μm or thicker and 1 μm or thinner, a range of 1 μm or thicker and 1.5 μm or thinner, a range of 1.5 μm or thicker and 2.5 μm or thinner, and a range of 2.5 μm or thicker and 5 μm or thinner.

Referring to FIG. 12F and FIG. 12G, the forming step of the electrode 77 includes an arranging step of a mask jig 78, a depositing step of the electrode 77, and a removing step of the mask jig 78 (refer to FIG. 12G). The mask jig 78 is a robust frame member that exposes the inner portion of the second surface 4 of the wafer 2, covers the peripheral edge portion of the second surface 4 of the wafer 2, and is formed in a flat band plate shape with an end or a flat band plate shape without an end.

The mask jig 78 may be formed in an arc plate shape, a circular arc plate shape, or an annular plate shape extending along the outer shape (peripheral end surface 5) of the wafer 2. In this embodiment, the mask jig 78 is formed in an annular plate shape, and has a mask opening 79 for exposing the inner portion of the second surface 4 as a region of the second surface 4 in which the electrode 77 is to be formed. The region in which the electrode 77 is to be formed (the inner portion of the second surface 4) is a region that opposes the plurality (all) of device regions 15 (device structures 18) in the thickness direction.

The mask jig 78 may be made of an inorganic plate-shaped member or an organic plate-shaped member. The mask jig 78 includes at least one of glass, ceramic, silicon, silicon carbide, carbon, sapphire, gallium nitride, gallium oxide, resin, or metal (for example, stainless steel, aluminum, or the like). In this embodiment, the mask jig 78 is made of a metal plate (for example, a stainless plate). The mask jig 78 has a thickness thicker than the thickness (total thickness) of the electrode 77.

In the arranging step of the mask jig 78, the mask jig 78 is arranged on the peripheral edge portion of the second surface 4. In this embodiment, the mask jig 78 covers the peripheral edge portion of the second surface 4 over the entire periphery. In the depositing step of the electrode 77, a single or a plurality of metal films are deposited by one or both of a sputtering method and a vapor deposition method. A single or a plurality of metal films are deposited such as to collectively cover the second surface 4 and the mask jig 78.

Referring to FIG. 12G and FIG. 16, in the removing step of the mask jig 78, the mask jig 78 is separated from above the second surface 4. In this step, a portion that covers the mask jig 78 in the single or plurality of metal films is removed together with the mask jig 78. Thereby, the electrode 77 that covers the inner portion of the second surface 4 and exposes the peripheral edge portion of the second surface 4 is formed.

The electrode 77 is located in the inner portion of the second surface 4 with respect to the first bevel portion 8, and does not oppose the first bevel portion 8 in the thickness direction. As a matter of course, the electrode 77 may partially oppose the first bevel portion 8 in the thickness direction. The electrode 77 may be located inwardly from the peripheral edge of the organic film 45, or may be located outwardly from the peripheral edge of the organic film 45. The electrode 77 may be located inwardly from the exclusion region 17, or may be located outwardly from the exclusion region 17.

The forming step of the electrode 77 may include annealing processing for the second surface 4 and the electrode 77 in order to enhance the ohmic property of the electrode 77 with respect to the second surface 4. The annealing processing may be a rapid thermal processing (RTP) method such as a lamp annealing method or a laser annealing method. The annealing processing may be performed before the forming step of the electrode 77, may be performed during the forming step of the electrode 77, or may be performed after the forming step of the electrode 77. The annealing processing step may include a step of forming one or both of a silicide layer and a silicon amorphous layer in the surface layer portion of the second surface 4. For example, the silicide layer may include at least one of a Ti silicide layer, an Ni silicide layer, or a Co silicide layer. Preferably, the silicide layer includes a Ti silicide layer.

Next, referring to FIG. 12H, the above-described second supporting member 61 is prepared, and is attached to the second surface 4 side of the wafer 2 (step S5 in FIG. 11). That is, the wafer structure 1 is supported by the second supporting member 61 from the second surface 4 side of the wafer 2. Thereby, the wafer support structure 75 including the wafer structure 1, the first supporting member 51, the second supporting member 61, and the electrode 77 is formed.

This step may include a step of attaching the wafer 2 to the second supporting member 61 from the second surface 4 side in a state where the second supporting member 61 is fixed. This step may include a step of attaching the second supporting member 61 to the second surface 4 of the wafer 2 in a state where the wafer 2 is fixed.

Referring also to FIG. 17, the second supporting member 61 is arranged on the peripheral edge portion of the second surface 4 such as to expose the inner portion of the second surface 4.

The second supporting member 61 is located on the peripheral edge portion side of the second surface 4 with respect to the plurality of device regions 15 (device structures 18), and does not oppose the plurality of device regions 15 (device structures 18) in the lamination direction. In this embodiment, the second supporting member 61 is arranged on the peripheral edge portion of the electrode 77, and covers the second surface 4 across the electrode 77.

The second supporting member 61 includes a portion that upwardly protrudes from above the electrode 77 toward a portion of the second surface 4 that is exposed from the electrode 77, and opposes the peripheral edge portion of the second surface 4 without interposing the electrode 77 in the lamination direction. In this embodiment, the second supporting member 61 covers the entire periphery of the peripheral edge portion of the second surface 4, and opposes the first bevel portion 8 in the lamination direction. The second supporting member 61 includes a protruding portion that protrudes outwardly from the peripheral end surface 5 of the wafer 2, and opposes the first supporting member 51 (first plate surface 52) without interposing the wafer 2 in the lamination direction. The outer end surface 64 of the second supporting member 61 provides protection for the peripheral end surface 5 of the wafer 2.

In a case where the second diameter D2 of the second supporting member 61 is smaller than the wafer diameter DW, in the diameter reduction step, the peripheral end surface 5 of the wafer 2 is removed until the wafer diameter DW becomes smaller than the second diameter D2. Therefore, according to the diameter reduction step, the wafer 2 can be reliably located inwardly from the outer end surface 64. Here, in this case, a removed area of the wafer 2 increases. Therefore, preferably, the second diameter D2 is set in advance to a value substantially equal to the wafer diameter DW or a value larger than the wafer diameter DW.

The second supporting member 61 is adhered to the second surface 4 side of the wafer 2 via a second adhesive member 80. That is, the wafer support structure 75 includes the second adhesive member 80 interposed between the second surface 4 of the wafer 2 and the first plate surface 62 of the second supporting member 61. In this embodiment, the second adhesive member 80 is made of a double-sided adhesive tape having a second peeling condition different from the first peeling condition (that is, one of a thermal peeling type and an ultraviolet peeling type) of the first adhesive member 76. The second peeling condition may be the other of the thermal peeling type and the ultraviolet peeling type.

In this embodiment, the second adhesive member 80 is interposed between the second supporting member 61 and the electrode 77, and adheres the second supporting member 61 to the second surface 4 of the wafer 2 via the electrode 77. The second adhesive member 80 extends in a film shape along the electrode 77. The second adhesive member 80 extends in a band shape along the second supporting member 61 (the peripheral edge portion of the electrode 77) in a plan view. In this embodiment, the second adhesive member 80 is formed in an annular shape (rounded annular shape) extending along the second supporting member 61 in a plan view, and is interposed in a region between the second supporting member 61 and the second surface 4 over the entire periphery.

The second adhesive member 80 includes an inner edge portion on the inner side of the second surface 4 and an outer edge portion on the peripheral edge portion side of the second surface 4. The inner edge portion of the second adhesive member 80 is located on the electrode 77. The inner edge portion of the second adhesive member 80 is formed at an interval from the inner end surface 65 toward the outer end surface 64 side, and forms a gap portion between the electrode 77 (second surface 4) and the inner edge portion of the second supporting member 61. A height of the gap portion is substantially equal to the thickness of the second adhesive member 80, and is extremely low (for example, 1 mm or lower).

The outer edge portion of the second adhesive member 80 is upwardly drawn from above the electrode 77 toward a portion of the peripheral edge portion of the second surface 4 that is exposed from the electrode 77, and includes a portion that is directly adhered to the peripheral edge portion of the second surface 4. The outer edge portion of the second adhesive member 80 is formed at an interval from the outer end surface 64 toward the inner end surface 65, and exposes the peripheral edge portion of the first plate surface 62.

The outer edge portion of the second adhesive member 80 exposes the peripheral end surface 5 of the wafer 2. Specifically, the outer edge portion of the second adhesive member 80 is formed at an interval from the peripheral end surface 5 of the wafer 2 toward the inner end surface 65 side, and exposes the peripheral edge portion of the second surface 4. Thereby, stress of the second adhesive member 80 on the peripheral edge portion of the second surface 4 is reduced, and a crack starting from the peripheral edge portion of the second surface 4 is suppressed.

In this embodiment, the outer edge portion of the second adhesive member 80 is formed at an interval inwardly from the first bevel portion 8, and does not oppose the first bevel portion 8 in the lamination direction. Thereby, stress of the second adhesive member 80 on the first bevel portion 8 (the thin portion of the wafer 2) is reduced, and a crack starting from the first bevel portion 8 is suppressed.

The outer edge portion of the second adhesive member 80 forms a gap portion between the peripheral edge portion of the second surface 4 and the first plate surface 62. A height of the gap portion is substantially equal to the total thickness of the thickness of the electrode 77 and the thickness of the second adhesive member 80, and is extremely low (for example, 1 mm or thinner).

As a matter of course, the outer edge portion of the second adhesive member 80 may be located on the electrode 77 at an interval inwardly from the peripheral edge of the electrode 77. That is, the entire second adhesive member 80 may be arranged on the electrode 77, and may expose the peripheral edge portion of the second surface 4 and the peripheral edge portion of the electrode 77.

Next, referring to FIG. 12I, a first removing step of separating the first supporting member 51 from the first surface 3 side is performed (step S6 in FIG. 11). In this step, the wafer support structure 75 that includes the wafer structure 1 and the second supporting member 61 and does not include the first supporting member 51 is formed. The first supporting member 51 is removed in a state of being supported by the second supporting member 61.

In a case where the first adhesive member 76 has the first peeling condition having a thermal peeling type, the first removing step includes a heating step for the first adhesive member 76 (wafer support structure 75). In this step, the adhesive force of the first adhesive member 76 is reduced by heating, and the first adhesive member 76 is peeled off from the wafer structure 1 and the first supporting member 51. Thereby, the first supporting member 51 is removed from the first surface 3 side.

On the other hand, in a case where the first adhesive member 76 has the first peeling condition having an ultraviolet peeling type, the first removing step includes an ultraviolet irradiation step for the first adhesive member 76. For example, the first adhesive member 76 is irradiated with ultraviolet rays via the first supporting member 51 that is transparent or semi-transparent. In this step, the adhesive force of the first adhesive member 76 is reduced by the ultraviolet rays, and the first adhesive member 76 is peeled off from the wafer structure 1 and the first supporting member 51. Thereby, the first supporting member 51 is removed from the first surface 3 side.

Since the second adhesive member 80 has the second peeling condition different from the first peeling condition of the first adhesive member 76, a reduction in the adhesive force of the second adhesive member 80 due to the first removing step is suppressed. Therefore, handling of the wafer structure 1 (wafer support structure 75) after the removing step of the first supporting member 51 is appropriately performed by the second supporting member 61. That is, the wafer 2 that is subjected to the thinning step is inevitably warped (deformed) due to weight of the wafer 2.

In this regard, the second supporting member 61 supports the wafer 2 in a horizontally extended state after the removing step of the first supporting member 51, and suppresses warpage (deformation) and breakage of the wafer 2.

Next, referring to FIG. 12J, a testing step of the wafer 2 in a state where the wafer 2 is supported by the second supporting member 61 is performed (step S7 in FIG. 11). The testing step includes an evaluation step of electrical characteristics of the wafer 2 (device structure 18). Here, as an example, a testing device 81 for testing electrical characteristics of each of the device structures 18 as an example of testing of the wafer 2 is illustrated.

The testing device 81 includes a chamber 82, a stage unit 83, a probe unit 84, and a tester device 85. Although not specifically illustrated, the chamber 82 includes partition walls that define an internal space (test space) and have a transfer door (for example, an opening/closing shutter) for loading and unloading the wafer 2.

The stage unit 83 is arranged in the chamber 82. The stage unit 83 includes a stage body 86 made of a conductor. The stage body 86 may be made of metal. The stage body 86 is formed in a plate shape (in this embodiment, a circular plate shape), and has a stage diameter DS smaller than the inner diameter D3 of the second supporting member 61. The stage body 86 includes a stage surface 87 and stage side walls 88. The stage surface 87 is a circular-shaped test surface on which the wafer 2 is arranged during the test, and has a flat surface extending in the horizontal direction. The stage side wall 88 extends in the vertical direction over the entire periphery of the stage surface 87.

In this embodiment, the stage unit 83 includes a housing portion 89 provided outwardly from the stage body 86. The housing portion 89 is an area in which the second supporting member 61 is housed when the wafer 2 is arranged on the stage surface 87. In this embodiment, the housing portion 89 is defined by a flange portion 90 extending outwardly from the stage side wall 88. The flange portion 90 is located on a lower side with respect to the stage surface 87 in the vertical direction, and includes a portion extending in the horizontal direction. In this embodiment, the flange portion 90 defines, together with the stage body 86 (the stage side wall 88), the housing portion 89 that has a recess shape and is recessed in one stage or multiple stages downwardly from the stage surface 87. As a matter of course, the flange portion 90 may include a portion (outer peripheral wall portion) extending upwardly in the vertical direction at a position separated from the stage side wall 88, and may define the housing portion 89 that has a groove shape and is recessed in one stage or multiple stages downwardly from the stage surface 87.

The probe unit 84 may be a manipulator system, or may be a cantilever system. The probe unit 84 includes one or a plurality of (in this embodiment, a plurality of) probe needles 91 corresponding to the number of terminals of the device structure 18. The number of probe needles 91 is adjusted according to the number of terminals. In this embodiment, the plurality of probe needles 91 include a first probe 91a for the gate terminal 41 and a second probe 91b for the source terminal 43.

The tester device 85 generates a predetermined electric signal (potential or current) to be applied to the wafer 2 (device structure 18), and outputs the generated electric signal to the stage unit 83 and the probe unit 84. In the tester device 85, various electrical characteristics such as switching response characteristics, a breakdown voltage, and a leakage current of the device structure 18 are tested.

For example, the tester device 85 generates a predetermined gate potential Vg, a predetermined source potential Vs, and a predetermined drain potential Vd, and respectively outputs the generated potentials to the stage body 86, the first probe 91a, and the second probe 91b. Thereby, the drain potential Vd is applied to the stage body 86, the gate potential Vg is applied to the first probe 91a, and the source potential Vs is applied to the second probe 91b.

The wafer 2 is loaded into the chamber 82 in a state of being supported by the second supporting member 61, and is arranged on the stage surface 87 (stage body 86) in a posture in which the second surface 4 opposes the stage surface 87. Thereby, the wafer 2 is electrically connected to the stage surface 87 via the electrode 77. Specifically, the plurality (in this embodiment, all) of device regions 15 (device structures 18) oppose the stage surface 87 in the vertical direction, and are electrically connected to the stage surface 87 via the electrode 77.

The second supporting member 61 is located in the housing portion 89 outside the stage surface 87. That is, the wafer support structure 75 is arranged such as to be fitted to the stage body 86. The second supporting member 61 is located at an interval from the stage side wall 88 in the horizontal direction, and opposes the stage side wall 88 in the horizontal direction. In this embodiment, the second supporting member 61 is separated from the stage side wall 88 over the entire periphery of the stage surface 87 in the peripheral direction, and opposes the stage side wall 88 in the horizontal direction.

The second supporting member 61 is arranged at a height position at an interval from the flange portion 90 (a bottom wall of the housing portion 89) toward the stage surface 87 side, and opposes the flange portion 90 in the vertical direction. In this embodiment, the second supporting member 61 opposes the flange portion 90 in the vertical direction over the entire periphery of the stage surface 87 in the peripheral direction.

The second supporting member 61 does not include a portion that comes into contact with the stage body 86 and the flange portion 90, and is electrically disconnected from both of the stage body 86 and the flange portion 90. Thereby, an undesirable current path via the second supporting member 61 is suppressed from being formed between the wafer 2 and the stage body 86. That is, a decrease in the test accuracy of the electrical characteristics that is caused by the second supporting member 61 is suppressed. As a matter of course, in a case where the insulation property of the second supporting member 61 is ensured, the second supporting member 61 may come into contact with the stage body 86 and the flange portion 90.

After the wafer support structure 75 is loaded, a predetermined gate potential Vg is applied from the first probe 91a to the gate terminal 41, a predetermined source potential Vs is applied from the second probe 91b to the source terminal 43, and a predetermined drain potential Vd is applied from the stage body 86 to the electrode 77. The gate potential Vg, the source potential Vs, and the drain potential Vd are appropriately adjusted according to electrical characteristics to be evaluated. Thereby, the electrical characteristics of the wafer 2 (device structure 18) are evaluated.

The testing step of the wafer 2 may include an appearance inspection step of the wafer 2. In this case, the wafer 2 is loaded into the appearance inspection device in a state of being supported by the second supporting member 61. In the appearance inspection device, an image of the wafer 2 when viewed from the first surface 3 side of the wafer 2 is acquired by an imaging device in a state where the wafer 2 is supported by the second supporting member 61, and an abnormality in the appearance of the wafer 2 is inspected based on the image. For example, the imaging device includes one or both of an image sensor having a charge coupled device (CCD) type and an image sensor having a complementary metal oxide semiconductor (CMOS) type.

In the wafer support structure 75, the second supporting member 61 is attached to the second surface 4 (non-device surface) side of the wafer 2, and a supporting member is not attached to the first surface 3 (device surface) side. Also, deformation (warpage) of the wafer 2 is suppressed by the second supporting member 61. Therefore, according to the wafer support structure 75, the appearance inspection step is not hindered by the second supporting member 61, and an abnormality in the appearance on the first surface 3 (device surface) side is appropriately detected.

Next, referring to FIG. 12K, a second removing step of separating the second supporting member 61 from the second surface 4 side is performed (step S8 in FIG. 11). In this step, first, a support tape 92 (first support tape) is prepared. The support tape 92 is made of a single-sided adhesive tape having a third peeling condition different from the second peeling condition of the second adhesive member 80. In a case where the second peeling condition is a thermal peeling type, the third peeling condition is an ultraviolet peeling type. In a case where the second peeling condition is an ultraviolet peeling type, the third peeling condition is a thermal peeling type. In this embodiment, the support tape 92 is a dicing tape.

Next, the support tape 92 is attached to the first surface 3 side of the wafer 2. This step may include a step of attaching the wafer 2 to the support tape 92 from the first surface 3 side in a state where the support tape 92 is fixed. This step may include a step of attaching the support tape 92 to the first surface 3 side of the wafer 2 in a state where the wafer 2 is fixed.

In this embodiment, the support tape 92 is adhered to the organic film 45. The support tape 92 may include a portion that is adhered to the gate terminal 41 via the gate pad opening 46. The support tape 92 may include a portion that is adhered to the source terminal 43 via the source pad opening 47. The support tape 92 may include a portion which is adhered to a portion of the first surface 3 that is exposed from the organic film 45.

Next, the second supporting member 61 is separated in a state where the wafer 2 is supported by the support tape 92. Thereby, the wafer structure 1 is released from the second supporting member 61, and handling of the wafer structure 1 by the wafer support structure 75 is ended. In a case where the second adhesive member 80 has the second peeling condition having a thermal peeling type, the second removing step includes a heating step for the second adhesive member 80 (wafer support structure 75). In this step, the adhesive force of the second adhesive member 80 is reduced by heating, and the second adhesive member 80 is peeled off from the wafer structure 1 and the second supporting member 61. Thereby, the second supporting member 61 is removed from the second surface 4 side.

On the other hand, in a case where the second adhesive member 80 has the second peeling condition having an ultraviolet peeling type, the second removing step includes an ultraviolet irradiation step for the second adhesive member 80. For example, the second adhesive member 80 is irradiated with ultraviolet rays via the second supporting member 61 that is transparent or semi-transparent. In this step, the adhesive force of the second adhesive member 80 is reduced by the ultraviolet rays, and the second adhesive member 80 is peeled off from the wafer structure 1 and the second supporting member 61. Thereby, the second supporting member 61 is removed from the second surface 4 side.

Since the support tape 92 has the third peeling condition different from the second peeling condition of the second adhesive member 80, a reduction in the adhesive force of the support tape 92 due to the second removing step is suppressed. Therefore, handling of the wafer structure 1 after the removing step of the second supporting member 61 is appropriately performed by the support tape 92. That is, the wafer 2 that is subjected to the thinning step is inevitably warped (deformed) due to weight of the wafer 2. In this regard, the support tape 92 supports the wafer 2 in a horizontally extended state after the removing step of the second supporting member 61, and suppresses warpage (deformation) and breakage of the wafer 2.

Thereafter, referring to FIG. 12L, the wafer structure 1 is cut along the intended cutting lines 16 in a state where the wafer 2 is supported by the support tape 92, and a plurality of device regions 15 (device structures 18) are cut out as a plurality of semiconductor devices SD (step S9 in FIG. 11). In this step, the wafer structure 1 is cut from the second surface 4 side to the first surface 3 side by a dicing saw. Thereafter, the plurality of semiconductor devices SD are separated from the support tape 92 through a heating step or an ultraviolet irradiation step for the support tape 92.

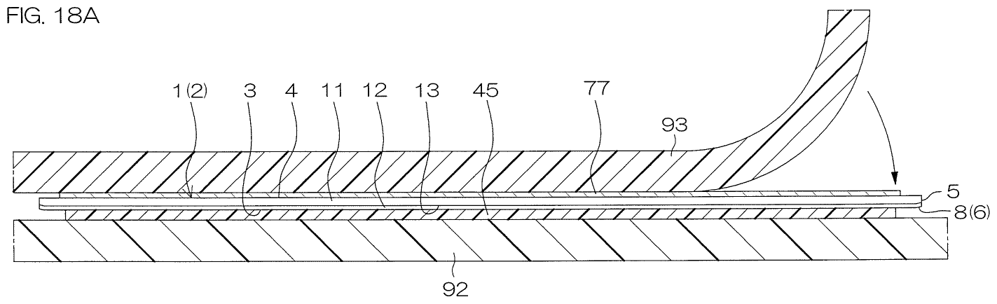

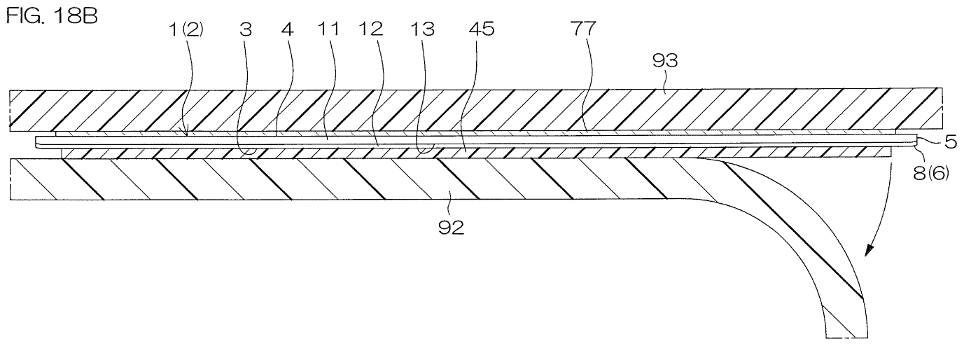

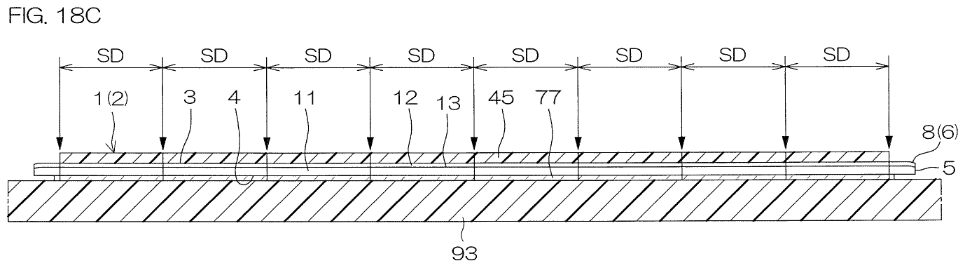

As illustrated in FIG. 18A to FIG. 18C, the wafer structure 1 may be cut from the first surface 3 side to the second surface 4 side. FIG. 18A to FIG. 18C are cross-sectional views illustrating another example of a dicing step (FIG. 12L). Referring to FIG. 18A, in a case where the wafer structure 1 is cut from the first surface 3 side to the second surface 4 side, a transfer tape 93 (second support tape) for remounting is prepared after the second removing step (step S8 in FIG. 11).

The transfer tape 93 is made of a single-sided adhesive tape having a fourth peeling condition different from the third peeling condition of the support tape 92. In a case where the third peeling condition is a thermal peeling type, the forth peeling condition is an ultraviolet peeling type. In a case where the third peeling condition is an ultraviolet peeling type, the fourth peeling condition is a thermal peeling type.

Next, the transfer tape 93 is attached to the second surface 4 side of the wafer 2. This step may include a step of attaching the wafer 2 to the transfer tape 93 from the second surface 4 side in a state where the transfer tape 93 is fixed. This step may include a step of attaching the transfer tape 93 to the second surface 4 side of the wafer 2 in a state where the wafer 2 is fixed. In this embodiment, the transfer tape 93 is adhered to the electrode 77. The transfer tape 93 may include a portion which is adhered to a portion of the peripheral edge portion of the second surface 4 that is exposed from the electrode 77. The transfer tape 93 may be adhered only to the electrode 77.

Next, referring to FIG. 18B, in a state where the wafer 2 is supported by the transfer tape 93, the support tape 92 is removed from the first surface 3 side. In a case where the support tape 92 has the third peeling condition having a thermal peeling type, the removing step of the support tape 92 includes a heating step for the support tape 92 (wafer support structure 75). In this step, the adhesive force of the support tape 92 is reduced by heating, and the support tape 92 is peeled off from the wafer structure 1.

On the other hand, in a case where the support tape 92 has the third peeling condition having an ultraviolet peeling type, the removing step of the support tape 92 includes a step of irradiating the support tape 92 with ultraviolet rays. In this step, the adhesive force of the support tape 92 is reduced by the ultraviolet rays, and the support tape 92 is peeled off from the wafer structure 1.

Thereafter, referring to FIG. 18C, the wafer structure 1 is cut along the intended cutting lines 16 in a state where the wafer 2 is supported by the transfer tape 93, and a plurality of device regions 15 (device structures 18) are cut out as a plurality of semiconductor devices SD. In this step, the wafer structure 1 is cut from the first surface 3 side toward the second surface 4 side by a dicing saw. Thereafter, the plurality of semiconductor devices SD are separated from the transfer tape 93 through a heating step or an ultraviolet irradiation step for the transfer tape 93. The plurality of semiconductor devices SD are manufactured from the wafer structure 1 through the steps including the above.

In this embodiment, as described above, the manufacturing method for the novel semiconductor device SD involving the processing of the wafer 2 is provided. The manufacturing method for the semiconductor device SD may include the preparation step (S1), the first supporting step (S3), the thinning step (S41), the second supporting step (S5), and the first removing step (S6).

In the preparation step (S1), the wafer 2 having the first surface 3 on one side and the second surface 4 on the other side may be prepared.

In the first supporting step (S3), the wafer 2 may be supported from the first surface 3 side by the plate-shaped first supporting member 51 (first member). In the thinning step (S41), the wafer 2 may be thinned in a state of being supported by the first supporting member 51. In the second supporting step (S5), the wafer 2 may be supported from the peripheral edge portion side of the second surface 4 by the plate-shaped second supporting member 61 that exposes the inner portion of the second surface 4 after the thinning step (S41). In the first removing step (S6), the first supporting member 51 may be separated from the first surface 3 side in a state where the wafer 2 is supported by the second supporting member 61.

According to this manufacturing method, deformation of the wafer 2 after the thinning step (S41) is suppressed by the first supporting member 51, and deformation of the wafer 2 after the first removing step (S6) is suppressed by the second supporting member 61. Thereby, the wafer 2 after the thinning step (S41) is appropriately handled. In the preparation step (S1), preferably, the wafer 2 including the SiC single crystal is prepared. According to this manufacturing method, the manufacturing method for an SiC semiconductor device is provided.

In the preparation step (S1), the wafer 2 having the first surface 3 as the device surface and the second surface 4 as the non-device surface may be prepared. In the preparation step (S1), the wafer 2 including the plurality of device structures 18 on the first surface 3 may be prepared. In the first supporting step (S3), the first supporting member 51 may support the wafer 2 from the first surface 3 side such as to oppose the plurality of device structures 18. In the second supporting step (S5), the second supporting member 61 may support the wafer 2 from the peripheral edge portion side of the second surface 4 so as not to oppose the plurality of device structures 18.

In the preparation step (S1), the wafer 2 having the thickness of 150 μm or thicker may be prepared. In the thinning step (S41), the wafer 2 may be thinned to the thickness thinner than 150 μm. In the preparation step (S1), the wafer 2 having the diameter equal to or larger than 6 inches may be prepared.

The first supporting member 51 may include at least one of glass, ceramic, silicon, silicon carbide, carbon, sapphire, gallium nitride, gallium oxide, resin, or metal. The first supporting member 51 may have the diameter equal to or larger than the diameter of the wafer 2. The first supporting member 51 may have the thickness equal to or thicker than the thickness of the wafer 2.

The second supporting member 61 may have an annular plate shape. The second supporting member 61 may include at least one of glass, ceramic, silicon, silicon carbide, carbon, sapphire, gallium nitride, gallium oxide, resin, or metal. The second supporting member 61 may have the diameter equal to or larger than the diameter of the wafer 2. The second supporting member 61 may have the thickness equal to or thicker than the thickness of the wafer 2.

In the first supporting step (S3), the first supporting member 51 may be adhered to the first surface 3 side via the first adhesive member 76. In the second supporting step (S5), the second supporting member 61 may be adhered to the second surface 4 side via the second adhesive member 80. The second adhesive member 80 may have the peeling condition different from the peeling condition of the first adhesive member 76. The first adhesive member 76 may have the peeling condition having one of the thermal peeling type and an ultraviolet peeling type. The second adhesive member 80 may have the peeling condition having the other of the thermal peeling type and an ultraviolet peeling type.

The manufacturing method for the semiconductor device SD may include the diameter reduction step (S2) of partially removing the peripheral end surface 5 of the wafer 2 before the first supporting step (S3). In the first supporting step (S3), the first supporting member 51 may support the wafer 2 after the diameter reduction. In the second supporting step (S5), the second supporting member 61 may support the wafer 2 after the diameter reduction.

In the preparation step (S1), the wafer 2 including one or both of the first bevel portion 8 and the second bevel portion 9 on the peripheral end surface 5 may be prepared. In the diameter reduction step (S2), a part or all of the first bevel portion 8 may be removed from the peripheral end surface 5. In the diameter reduction step (S2), a part or all of the second bevel portion 9 may be removed from the peripheral end surface 5.

The manufacturing method for the semiconductor device SD may include the step (S43) of forming the electrode 77 on the second surface 4 after the thinning step (S41). The second supporting step (S5) may be performed after the forming step of the electrode 77.

The manufacturing method for the semiconductor device SD may include the testing step (S7) of testing the wafer 2 in a state where the wafer 2 is supported by the second supporting member 61 after the first removing step (S6). The manufacturing method for the semiconductor device SD may include the second removing step (S8) of removing the second supporting member 61 from the second surface 4 side after the testing step (S7).

From another point of view, the manufacturing method for the semiconductor device SD may include the preparation step (S1), the first supporting step (S3), and the processing step (S4) of the wafer 2. In the preparation step (S1), the wafer 2 having the first surface 3 on one side and the second surface 4 on the other side may be prepared. In the first supporting step (S3), the plate-shaped first supporting member 51 (supporting member) may be adhered to the first surface 3 side via the first adhesive member 76, and the wafer 2 may be supported by the first supporting member 51 from the first surface 3 side.

In the processing step (S4), the wafer 2 may be processed in a state of being supported by the first supporting member 51. According to this manufacturing method, since the wafer 2 is supported by the first supporting member 51, the processing step (S4) for the wafer 2 is appropriately performed. Also, the wafer 2 is appropriately handled before and after the processing step (S4). In the preparation step (S1), the wafer 2 including the SiC single crystal may be prepared. According to this manufacturing method, the manufacturing method for an SiC semiconductor device is provided.

In the first supporting step (S3), the first adhesive member 76 may be interposed between the wafer 2 and the supporting member such as to expose the peripheral end surface 5 of the wafer 2. In the first supporting step (S3), the first adhesive member 76 may be located closer to the inner portion side of the wafer 2 than the peripheral end surface 5 of the wafer 2, and may expose the peripheral edge portion of the first surface 3. In the first supporting step (S3), the first adhesive member 76 may expose the peripheral edge portion of the first supporting member 51.

In the preparation step (S1), the wafer 2 having the first surface 3 as the device surface and the second surface 4 as the non-device surface may be prepared. In the preparation step (S1), the wafer 2 including the plurality of device structures 18 on the first surface 3 may be prepared. In the first supporting step (S3), the first supporting member 51 may support the wafer 2 from the first surface 3 side such as to oppose all of the device structures 18.

The first supporting member 51 may include at least one of glass, ceramic, silicon, silicon carbide, carbon, sapphire, gallium nitride, gallium oxide, resin, or metal. The first supporting member 51 may have the diameter equal to or larger than the diameter of the wafer 2. The first supporting member 51 may have the thickness equal to or thicker than the thickness of the wafer 2.

The processing step (S4) may include the thinning step (S41) of thinning the wafer 2 in a state where the wafer 2 is supported by the first supporting member 51. The processing step (S4) may include the wet step (S42) of processing the second surface 4 with the processing liquid in a state where the wafer 2 is supported by the first supporting member 51. The processing step (S4) may include the step (S42) of forming the electrode 77 on the second surface 4 in a state where the wafer 2 is supported by the first supporting member 51.

The manufacturing method for the semiconductor device SD may include the diameter reduction step (S2) of partially removing the peripheral end surface 5 of the wafer 2 before the first supporting step (S3). In the first supporting step (S3), the first supporting member 51 may be adhered to the first surface 3 side of the wafer 2 after the diameter reduction via the first adhesive member 76.

In the preparation step (S1), the wafer 2 including one or both of the first bevel portion 8 and the second bevel portion 9 on the peripheral end surface 5 may be prepared. In the diameter reduction step (S2), a part or all of the first bevel portion 8 may be removed from the peripheral end surface 5. In the diameter reduction step (S2), a part or all of the second bevel portion 9 may be removed from the peripheral end surface 5.

The manufacturing method for the semiconductor device SD may include the second supporting step (S5) of supporting the wafer 2 from the second surface 4 side by the plate-shaped second supporting member 61 after the processing step (S4). The manufacturing method for the semiconductor device SD may include the first removing step (S6) of removing the first supporting member 51 from the first surface 3 side in a state where the wafer 2 is supported by the second supporting member 61.

The second supporting step (S5) may include the step of adhering the second supporting member 61 to the second surface 4 side via the second adhesive member 80. The second adhesive member 80 may have the peeling condition different from the peeling condition of the first adhesive member 76. The first adhesive member 76 may have the peeling condition having one of the thermal peeling type and an ultraviolet peeling type. The second adhesive member 80 may have the peeling condition having the other of the thermal peeling type and an ultraviolet peeling type.

The manufacturing method for the semiconductor device SD may include the testing step (S7) of testing the wafer 2 in a state where the wafer 2 is supported by the second supporting member 61 after the removing step. The manufacturing method for the semiconductor device SD may include the second removing step (S8) of removing the second supporting member 61 from the second surface 4 side after the testing step (S7).

From another point of view, according to the manufacturing method for the semiconductor device SD, a novel wafer support structure 75 involving processing of the wafer 2 is provided. The wafer support structure 75 may include the first supporting member 51 and the wafer 2. The wafer 2 may include the first surface 3 as the device surface, the second surface 4 as the non-device surface, and the peripheral end surface 5 that connects the first surface 3 and the second surface 4. The wafer 2 may be arranged on the first supporting member 51 in a posture in which the first surface 3 opposes the first supporting member 51.

According to the wafer support structure 75, the wafer 2 is appropriately handled. The wafer 2 may include an SiC single crystal. According to this configuration, the SiC semiconductor device is manufactured using the wafer 2 including the SiC single crystal.

The first surface 3 may include the first corner portion 6 including the first bevel portion 8. The second surface 4 may include the second corner portion 7 that does not include the bevel portion (second bevel portion 9). The first bevel portion 8 may oppose the first supporting member 51 in the lamination direction. The second corner portion 7 may be angular. The second surface 4 may be the ground surface. The peripheral end surface 5 may be the ground surface. The wafer 2 may have the thickness equal to or thinner than 100 μm.

The first supporting member 51 may have a plate shape having the diameter equal to or larger than the diameter of the wafer 2. The wafer 2 may be arranged on the first supporting member 51 at an interval inwardly from the peripheral edge of the first supporting member 51. The first supporting member 51 may have the thickness equal to or thicker than the thickness of the wafer 2. The first supporting member 51 may include at least one of glass, ceramic, silicon, silicon carbide, carbon, sapphire, gallium nitride, gallium oxide, resin, or metal.

The wafer support structure 75 may include an electrode 77 that covers the second surface 4. The electrode 77 may expose the peripheral edge portion of the second surface 4. The wafer support structure 75 may include the second supporting member 61 that is arranged on the second surface 4 of the wafer 2. The second supporting member 61 may have an annular plate shape, and may be arranged on the peripheral edge portion of the second surface 4 such as to expose the inner portion of the second surface 4.

The second supporting member 61 may have the diameter equal to or larger than the diameter of the wafer 2. The second supporting member 61 may be arranged on the peripheral edge portion of the second surface 4 such as to protrude outwardly from the peripheral end surface 5. The second supporting member 61 may have the thickness equal to or thicker than the thickness of the wafer 2. The second supporting member 61 may include at least one of glass, ceramic, silicon, silicon carbide, carbon, sapphire, gallium nitride, gallium oxide, resin, or metal.

From another point of view, the wafer support structure 75 may include the first supporting member 51, the wafer 2, the electrode 77, and the second supporting member 61. The first supporting member 51 may have a plate shape. The wafer 2 may include the first surface 3 as the device surface, the second surface 4 as the non-device surface, and the peripheral end surface 5 that connects the first surface 3 and the second surface 4. The wafer 2 may be arranged on the first supporting member 51 in a posture in which the first surface 3 opposes the first supporting member 51. The electrode 77 may cover the second surface 4. The second supporting member 61 may have an annular plate shape. The second supporting member 61 may be arranged on the electrode 77.

According to the wafer support structure 75, the wafer 2 is appropriately handled. The wafer 2 may include an SiC single crystal. According to this configuration, the SiC semiconductor device is manufactured using the wafer 2 including the SiC single crystal. The first surface 3 may include the first corner portion 6 including the first bevel portion 8. The second surface 4 may be the ground surface. The second surface 4 may include the second corner portion 7 that is angular. The peripheral end surface 5 may be the ground surface.

From another point of view, the wafer support structure 75 may include the first supporting member 51, the wafer 2, and the first adhesive member 76. The wafer 2 may include the first surface 3 as the device surface, the second surface 4 as the non-device surface, and the peripheral end surface 5 that connects the first surface 3 and the second surface 4. The wafer 2 may be arranged on the first supporting member 51 in a posture in which the first surface 3 opposes the first supporting member 51. The first adhesive member 76 may be interposed between the first supporting member 51 and the first surface 3.

According to the wafer support structure 75, the wafer 2 is appropriately handled. The wafer 2 may include an SiC single crystal. According to this configuration, the SiC semiconductor device is manufactured using the wafer 2 including the SiC single crystal.

The first adhesive member 76 may be arranged at an interval inwardly from the peripheral edge of the first supporting member 51, and expose the peripheral edge portion of the first supporting member 51. The first adhesive member 76 may be arranged at an interval inwardly from the peripheral end surface 5 of the wafer 2, and expose the peripheral edge portion of the first surface 3. The first surface 3 may include the first corner portion 6 including the first bevel portion 8. The first adhesive member 76 may expose the first bevel portion 8. The second surface 4 may not include the bevel portion (second bevel portion 9), and may include the second corner portion 7 that is angular. The second surface 4 may be the ground surface. The peripheral end surface 5 may be the ground surface.

The first supporting member 51 may have a plate shape having the diameter equal to or larger than the diameter of the wafer 2. The wafer 2 may be arranged on the first supporting member 51 at an interval inwardly from the peripheral edge of the first supporting member 51. The first supporting member 51 may have the thickness equal to or thicker than the thickness of the wafer 2.

The wafer support structure 75 may include an electrode 77 that covers the second surface 4. The wafer support structure 75 may include the second supporting member 61 that is arranged on the second surface 4. The wafer support structure 75 may include the second adhesive member 80 interposed between the second surface 4 and the second supporting member 61.

From another point of view, the wafer support structure 75 may include the first supporting member 51, the wafer 2, the electrode 77, the second supporting member 61, the first adhesive member 76, and the second adhesive member 80. The first supporting member 51 may have a plate shape. The wafer 2 may include the first surface 3 as the device surface, the second surface 4 as the non-device surface, and the peripheral end surface 5 that connects the first surface 3 and the second surface 4. The wafer 2 may be arranged on the first supporting member 51 in a posture in which the first surface 3 opposes the first supporting member 51.

The electrode 77 may cover the second surface 4. The second supporting member 61 may be arranged on the electrode 77. The first adhesive member 76 may be interposed between the first supporting member 51 and the first surface 3. The second adhesive member 80 may be interposed between the electrode 77 and the second supporting member 61.

According to the wafer support structure 75, the wafer 2 is appropriately handled. The wafer 2 may include an SiC single crystal. According to this configuration, the SiC semiconductor device is manufactured using the wafer 2 including the SiC single crystal.

The second adhesive member 80 may have the peeling condition different from the peeling condition of the first adhesive member 76. The first adhesive member 76 may have the peeling condition having one of the thermal peeling type and an ultraviolet peeling type. The second adhesive member 80 may have the peeling condition having the other of the thermal peeling type and an ultraviolet peeling type.

The first adhesive member 76 may be arranged at an interval inwardly from the peripheral end surface 5 of the wafer 2, and expose the peripheral edge portion of the first surface 3. The second adhesive member 80 may be arranged at an interval inwardly from the peripheral end surface 5 of the wafer 2, and expose the peripheral edge portion of the second surface 4. The electrode 77 may expose the peripheral edge portion of the second surface 4. The second adhesive member 80 may cover a portion of the peripheral edge portion of the second surface 4 that is exposed from the electrode 77.

The first surface 3 may include the first corner portion 6 including the first bevel portion 8. The second surface 4 may be the ground surface. The second surface 4 may include the second corner portion 7 that is angular. The peripheral end surface 5 may be the ground surface.

From another point of view, the wafer support structure 75 may include the wafer 2 and the second supporting member 61. The wafer 2 may include the first surface 3 as the device surface, the second surface 4 as the non-device surface, and the peripheral end surface 5 that connects the first surface 3 and the second surface 4. The second supporting member 61 may be arranged on the peripheral edge portion of the second surface 4 such as to expose the inner portion of the second surface 4.

According to the wafer support structure 75, the wafer 2 is appropriately handled. The wafer 2 may include an SiC single crystal. According to this configuration, the SiC semiconductor device is manufactured using the wafer 2 including the SiC single crystal.

From another point of view, the wafer support structure 75 may include the wafer 2, the electrode 77, the second supporting member 61, and the second adhesive member 80. The wafer 2 may include the first surface 3 as the device surface, the second surface 4 as the non-device surface, and the peripheral end surface 5 that connects the first surface 3 and the second surface 4. The electrode 77 may cover the second surface 4. The second supporting member 61 may have an annular plate shape. The second supporting member 61 may be arranged on the electrode 77. The second adhesive member 80 may be interposed between the second supporting member 61 and the electrode 77.

According to the wafer support structure 75, the wafer 2 is appropriately handled. The wafer 2 may include an SiC single crystal. According to this configuration, the SiC semiconductor device is manufactured using the wafer 2 including the SiC single crystal.

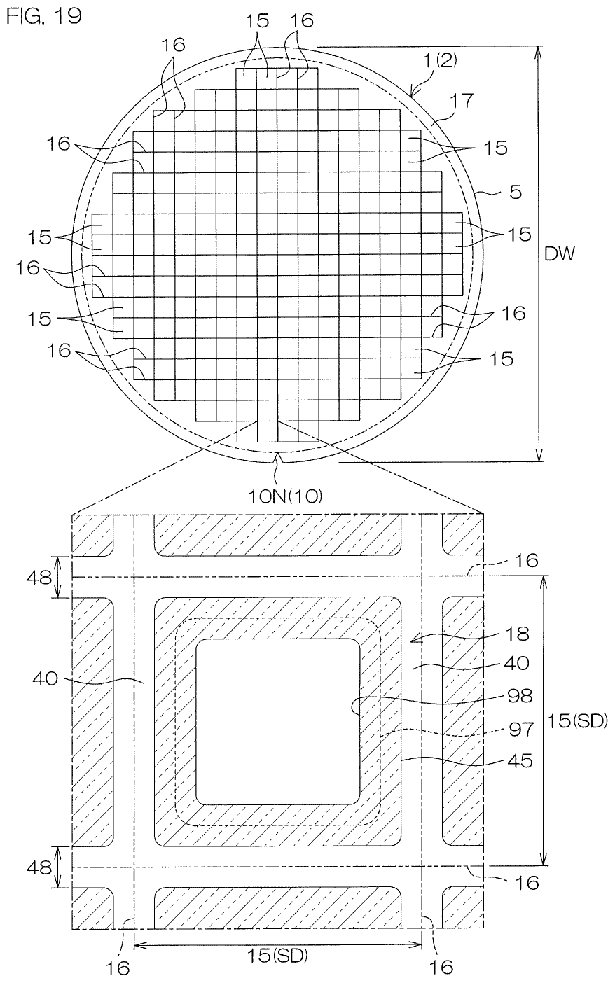

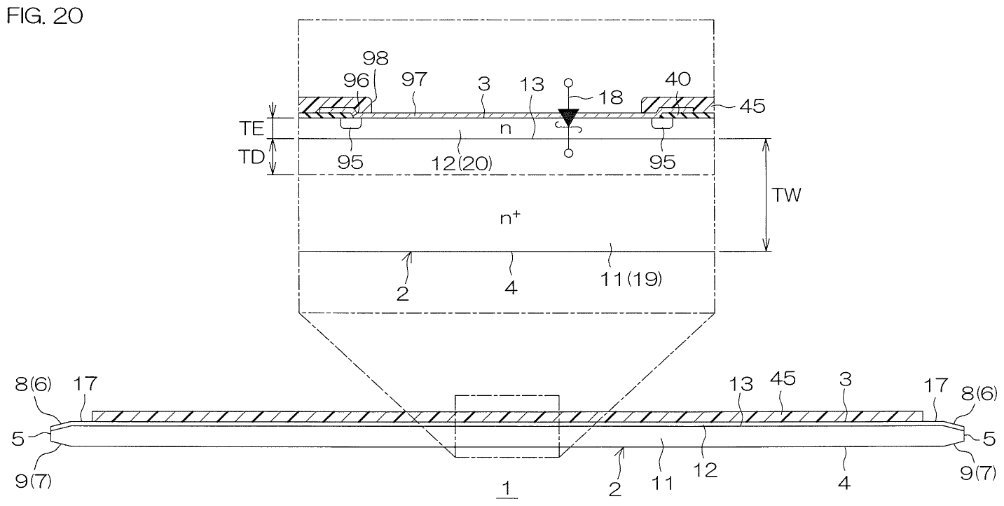

FIG. 19 is a plan view illustrating the wafer structure 1 (device structure 18) according to another example. FIG. 20 is a cross-sectional view illustrating the wafer structure 1 (device structure 18) according to another example. The wafer structure 1 described above has the transistor structure as an example of the device structure 18. On the other hand, the wafer structure 1 according to another example has a diode structure as an example of the device structure 18. In this embodiment, the above-described first semiconductor region 19 is formed as a “cathode region.” Hereinafter, a structure of one device region 15 (diode structure) will be described.

The wafer structure 1 according to another example includes a p-type impurity region 95 that is formed in the surface layer portion of the first surface 3. The impurity region 95 is formed in a surface layer portion of the second semiconductor region 20 (that is, the epitaxial layer 12). The impurity region 95 is formed in a polygonal annular shape (in this embodiment, a quadrangular annular shape) surrounding the inner portion of the device region 15 in a plan view. The impurity region 95 is formed at an interval from the bottom portion of the second semiconductor region 20 toward the first surface 3 side, and opposes the first semiconductor region 19 with a portion of the second semiconductor region 20 interposed therebetween.

The wafer structure 1 according to another example includes the interlayer film 40 that selectively covers the first surface 3 as in the case of the transistor structure. The interlayer film 40 is formed over almost the entire region of the first surface 3, and has an opening 96 for selectively exposing the first surface 3. In this embodiment, the opening 96 has an opening wall surface located on the impurity region 95, and exposes the second semiconductor region 20 and an inner edge portion of the impurity region 95. The opening wall surface is formed in a polygonal shape (in this embodiment, a quadrangular shape) extending along the impurity region 95 in a plan view, and exposes an inner edge portion of the impurity region 95 over the entire periphery.

The wafer structure 1 according to another example includes an anode terminal 97 arranged on the first surface 3. The anode terminal 97 is formed in a polygonal shape (in this embodiment, a quadrangular shape) along the peripheral edge of the device region 15 in a plan view. The anode terminal 97 enters the opening 96 from above the interlayer film 40, and is electrically connected to the second semiconductor region 20 and the inner edge portion of the impurity region 95 in the opening 96. The anode terminal 97 forms a Schottky junction with the second semiconductor region 20. Thereby, an SBD structure as an example of a diode structure is formed in the device region 15.

The wafer structure 1 according to another example includes the organic film 45 that covers the first surface 3 as in the case of the transistor structure. The organic film 45 is formed on the interlayer film 40, and covers the first surface 3 across the interlayer film 40. The organic film 45 covers the inner portion of the first surface 3 in a film shape. Specifically, the organic film 45 selectively covers a region of the first surface 3 that is located inwardly from the exclusion region 17.

The organic film 45 selectively covers the anode terminal 97 on the interlayer film 40. The organic film 45 covers the entire region of at least a portion of the first surface 3 that is located inwardly from the exclusion region 17. In this embodiment, the organic film 45 has an anode pad opening 98 and the street opening 48. An inner portion of the anode pad opening 98 is exposed.

Although not specifically illustrated, the wafer structure 1 may include an inorganic film that has an insulating property and is interposed between the interlayer film 40 and the organic film 45. The inorganic film is formed as an uppermost insulating film of the interlayer film 40. For example, the inorganic film may include at least one of a silicon nitride film, a silicon oxynitride film, or a silicon oxide film. The inorganic film selectively covers the anode terminal 97. The inorganic film may include a portion interposed between the anode terminal 97 and the organic film 45.

In a case where the wafer structure 1 according to another example is adopted, in the electrode formation step (S43), the electrode 77 described above is formed as a cathode terminal. Also, in the testing step (S7), an anode potential is applied from the probe needle 91 to the anode terminal 97, and a cathode potential is applied from the stage body 86 (stage surface 87) to the electrode 77. As described above, even in a case where the wafer structure 1 according to another example is adopted, the manufacturing method for the novel semiconductor device SD and the novel wafer support structure 75 involving the processing of the wafer 2 are provided.

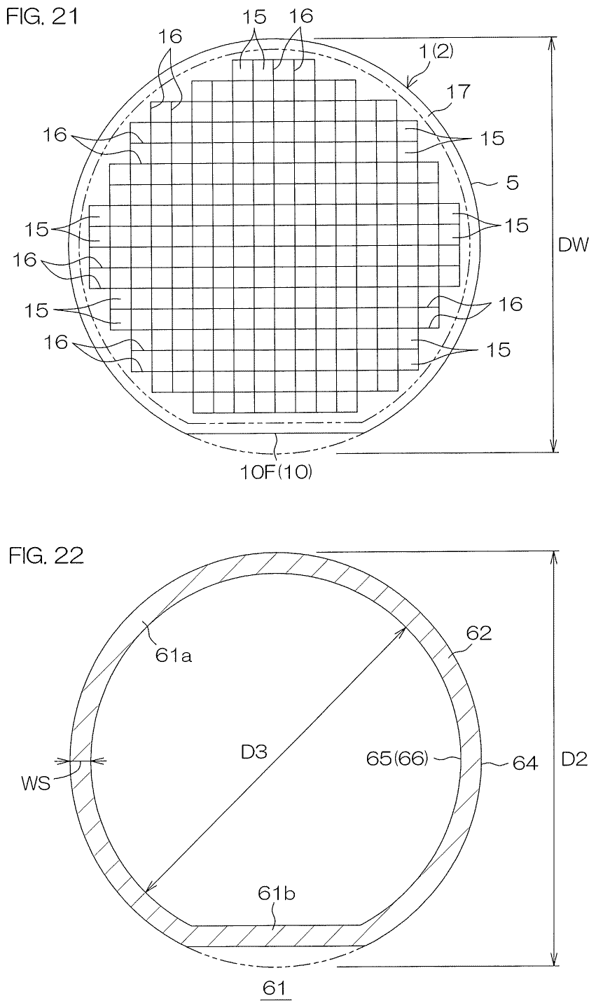

Hereinafter, another example of the wafer 2 (mark 10) will be described. FIG. 21 is a plan view illustrating the wafer 2 (mark 10) according to another example. FIG. 22 is a plan view illustrating the second supporting member 61 that can be used in combination with the wafer 2 (mark 10) according to another example.

The wafer 2 described above includes the notched portion 10N as an example of the mark 10. Here, the mark 10 may include a flat portion 10F instead of the notched portion 10N. The flat portion 10F may be referred to as an “orientation flat.” The flat portion 10F is formed of a notched portion extending in a straight line shape along the a-axis direction or the m-axis direction.

Referring to FIG. 22, in a case where the wafer 2 includes the flat portion 10F, the second supporting member 61 may include a first portion 61a that extends in a circular arc band shape along a portion other than the flat portion 10F of the wafer 2, and a second portion 61b that extends in a straight band shape along the flat portion 10F of the wafer 2. As a matter of course, even in a case where the wafer 2 includes the flat portion 10F, the second supporting member 61 may be formed in a rounded annular shape without the second portion 61b.

The above-described embodiment (including modification examples) can be implemented in still other forms. For example, in the embodiment described above, the first adhesive member 76 that exposes the peripheral edge portion of the first surface 3 has been exemplified. On the other hand, in a case where a crack or the like in the peripheral edge portion of the wafer 2 is not a problem, the first adhesive member 76 that covers the peripheral edge portion of the first surface 3 including the first bevel portion 8 may be adopted.

In this case, the first adhesive member 76 may cover almost the entire region of the first surface 3. For example, the first adhesive member 76 may include a portion that protrudes outwardly from the peripheral end surface 5 of the wafer 2. For example, the first adhesive member 76 may cover the entire region of the first plate surface 52 of the first supporting member 51.

In the embodiment described above, the second adhesive member 80 that exposes the peripheral edge portion of the second surface 4 is exemplified. On the other hand, in a case where a crack or the like in the peripheral edge portion of the wafer 2 is not a problem, the second adhesive member 80 that covers the peripheral edge portion of the second surface 4 such as to oppose the first bevel portion 8 in the lamination direction may be adopted.

In this case, the second adhesive member 80 may cover almost the entire region of the first plate surface 62 of the second supporting member 61. For example, the second adhesive member 80 may include a portion that protrudes inwardly from the inner end surface 65 of the second supporting member 61. For example, the second adhesive member 80 may include a portion that protrudes outwardly from the outer end surface 64 of the second supporting member 61.

In the above-described embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and accompanying drawings.

In the embodiment described above, the wafer 2 including an SiC single crystal is adopted. On the other hand, the wafer 2 may include a wide bandgap semiconductor single crystal other than the SiC single crystal. For example, the wafer 2 may include gallium nitride, gallium oxide, diamond, or the like. As a matter of course, the wafer 2 may include a silicon single crystal.

Similarly, the wafer body 11 may include a wide bandgap semiconductor single crystal other than the SiC single crystal. The wafer body 11 may include gallium nitride, gallium oxide, diamond, or the like. As a matter of course, the wafer body 11 may include a silicon single crystal.

Similarly, the epitaxial layer 12 may include a wide bandgap semiconductor single crystal other than the SiC single crystal. The epitaxial layer 12 may include gallium nitride, gallium oxide, diamond, or the like. As a matter of course, the epitaxial layer 12 may include a silicon single crystal.

In the embodiment described above, the wafer 2 made of an epitaxial wafer including the wafer body 11 and the epitaxial layer 12 has been exemplified. On the other hand, the wafer 2 does not necessarily include the epitaxial layer 12, and may have a single layer structure including the wafer body 11. A specific configuration in this case is obtained by setting the epi thickness TE of the epitaxial layer 12 to 0 (TE=0 μm) in the above description and the accompanying drawings. In the embodiment described above, the n-type first semiconductor region 19 has been

exemplified. On the other hand, a p-type first semiconductor region 19 may be adopted instead of the n-type first semiconductor region 19. In this case, an insulated gate bipolar transistor (IGBT) structure is formed instead of the MISFET structure. In this case, in the above descriptions, the “source” of the MISFET structure is replaced with an “emitter” of the IGBT structure and the “drain” of the MISFET structure is replaced with a “collector” of the IGBT structure. The p-type first semiconductor region 19 may be formed by introducing p-type impurities into the surface layer portion of the second surface 4 of the n-type wafer 2 (wafer body 11) by an ion implantation method.

In the embodiment described above, an SBD structure (Schottky barrier diode) as an example of a diode structure has been exemplified. On the other hand, the diode structure may include at least one of a pn junction diode, a pin junction diode, a Zener diode, or a fast recovery diode. In these cases, the diode structure may include one or a plurality of p-type anode regions forming a pn junction portion with the first semiconductor region 19 and/or the second semiconductor region 20 in the surface layer portion of the first surface 3.

Hereinafter, examples of features extracted from this description and the attached drawings are indicated. Hereinafter, the alphanumeric characters and the like in parentheses represent the corresponding components and the like in the embodiments described above, but are not intended to limit the scope of each clause to the embodiments described above. The “semiconductor device” according to the following items may be replaced with an “SiC semiconductor device,” a “wide bandgap semiconductor device,” a “semiconductor switching device,” a “MISFET device,” an “IGBT device,” a “semiconductor rectifier device,” or the like, as necessary.

[A1] A manufacturing method (S1 to S9) for a semiconductor device (SD) comprising: a preparation step (S1) of preparing a wafer (2) that has a first surface (3) on one side and a second surface (4) on the other side; a first supporting step (S3) of supporting the wafer (2) from the first surface (3) side by a first member (51) of plate shape; a thinning step (S41) of thinning the wafer (2) in a state where the wafer (2) is supported by the first member (51); a second supporting step (S5) of supporting the wafer (2) from a peripheral edge portion side of the second surface (4) by a second member (61) of plate shape that exposes an inner portion of the second surface (4) after the thinning step (S41); and a removing step (S6) of removing the first member (51) from the first surface (3) side in a state where the wafer (2) is supported by the second member (61).

[A2] The manufacturing method (S1 to S9) for the semiconductor device (SD) according to A1, wherein the wafer (2) that includes an SiC single crystal is prepared in the preparation step (S1).

[A3] The manufacturing method (S1 to S9) for the semiconductor device (SD) according to A1 or A2, wherein the wafer (2) that has the first surface (3) as a device surface and the second surface (4) as a non-device surface is prepared in the preparation step (S1).

[A4] The manufacturing method (S1 to S9) for the semiconductor device (SD) according to A3, wherein the wafer (2) that has device structures (18) on the first surface (3) is prepared in the preparation step (S1), the first member (51) supports the wafer (2) from the first surface (3) side such as to oppose the device structures (18) in the first supporting step (S3), and the second member (61) supports the wafer (2) from the peripheral edge portion side of the second surface (4) so as not to oppose the device structures (18) in the second supporting step (S5).

[A5] The manufacturing method (S1 to S9) for the semiconductor device (SD) according to any one of A1 to A4, wherein the wafer (2) that has a thickness (TW, TD, TE) equal to or thicker than 150 μm is prepared in the preparation step (S1), and the wafer (2) is thinned to a thickness (TW, TD, TE) thinner than 150 μm in the thinning step (S41).

[A6] The manufacturing method (SI to S9) for the semiconductor device (SD) according to any one of A1 to A5, wherein the wafer (2) that has a diameter (DW) equal to or larger than 6 inches is prepared in the preparation step (S1).

[A7] The manufacturing method (S1 to S9) for the semiconductor device (SD) according to any one of A1 to A6, wherein the first member (51) includes at least one of glass, ceramic, silicon, silicon carbide, carbon, sapphire, gallium nitride, gallium oxide, resin, or metal.

[A8] The manufacturing method (S1 to S9) for the semiconductor device (SD) according to any one of A1 to A7, wherein the first member (51) has a diameter (D1) equal to or larger than a diameter (DW) of the wafer (2).

[A9] The manufacturing method (S1 to S9) for the semiconductor device (SD) according to any one of A1 to A8, wherein the first member (51) has a thickness (T1) equal to or thicker than a thickness (TW, TD, TE) of the wafer (2).

[A10] The manufacturing method (S1 to S9) for the semiconductor device (SD) according to any one of A1 to A9, wherein the second member (61) has an annular plate shape.

[A11] The manufacturing method (SI to S9) for the semiconductor device (SD) according to any one of A1 to A10, wherein the second member (61) includes at least one of glass, ceramic, silicon, silicon carbide, carbon, sapphire, gallium nitride, gallium oxide, resin, or metal.

[A12] The manufacturing method (S1 to S9) for the semiconductor device (SD) according to any one of A1 to A11, wherein the second member (61) has a diameter (D2) equal to or larger than a diameter (DW) of the wafer (2).

[A13] The manufacturing method (S1 to S9) for the semiconductor device (SD) according to any one of A1 to A12, wherein the second member (61) has a thickness (T2) equal to or thicker than a thickness (TW, TD, TE) of the wafer (2).

[A14] The manufacturing method (S1 to S9) for the semiconductor device (SD) according to any one of A1 to A13, wherein the first member (51) is adhered to the first surface (3) side via a first adhesive member (76) in the first supporting step (S3) and the second member (61) is adhered to the second surface (4) side via a second adhesive member (80) in the second supporting step (S5).

[A15] The manufacturing method (S1 to S9) for the semiconductor device (SD) according to A14, wherein the second adhesive member (80) has a peeling condition different from a peeling condition of the first adhesive member (76).

[A16] The manufacturing method (S1 to S9) for the semiconductor device (SD) according to A15, wherein the first adhesive member (76) has a peeling condition having one of a thermal peeling type and an ultraviolet peeling type, and the second adhesive member (80) has a peeling condition having the other of the thermal peeling type and the ultraviolet peeling type.

[A17] The manufacturing method (S1 to S9) for the semiconductor device (SD) according to any one of A1 to A16, further comprising: a diameter reduction step (S2) of partially removing a peripheral end surface (5) of the wafer (2) before the first supporting step (S3); and wherein the first member (51) supports the wafer (2) after the diameter reduction in the first supporting step (S3), and the second member (61) supports the wafer (2) after the diameter reduction in the second supporting step (S5).

[A18] The manufacturing method (S1 to S9) for the semiconductor device (SD) according to A17, wherein the wafer (2) that includes a bevel portion (8, 9) in the peripheral end surface (5) are prepared in the preparation step (S1), and a part or all of the bevel portion (8, 9) is removed from the peripheral end surface (5) in the diameter reduction step (S2).

[A19] The manufacturing method (S1 to S9) for the semiconductor device (SD) according

to any one of A1 to A18, further comprising: a step of forming an electrode (77) on the second surface (4) after the thinning step (S41); and wherein the second supporting step (S5) is performed after the forming step of the electrode (77).

[A20] The manufacturing method (S1 to S9) for the semiconductor device (SD) according to any one of A1 to A19, further comprising: a testing step (S7) of testing the wafer (2) in a state where the wafer (2) is supported by the second member (61) after the removing step (S6); and a second removing step (S8) of removing the second member (61) from the second surface (4) side after the testing step (S7).

[B1] A manufacturing method (S1 to S9) for a semiconductor device (SD) comprising: a preparation step (S1) of preparing a wafer (2) that has a first surface (3) on one side and a second surface (4) on the other side; a supporting step (S3) of adhering a supporting member (51) of a plate shape to the first surface (3) side via an adhesive member (76); and a processing step (S4) of processing the wafer (2) in a state where the wafer (2) is supported by the supporting member (51).

[B2] The manufacturing method (S1 to S9) for the semiconductor device (SD) according to B1, wherein the wafer (2) that includes an SiC single crystal is prepared in the preparation step (S1).

[B3] The manufacturing method (S1 to S9) for the semiconductor device (SD) according to B1 or B2, wherein the adhesive member (76) is interposed between the wafer (2) and the supporting member (51) such as to expose a peripheral end surface (5) of the wafer (2) in the supporting step (S3).

[B4] The manufacturing method (S1 to S9) for the semiconductor device (SD) according to B3, wherein the adhesive member (76) is located closer to an inner portion side of the wafer (2) than the peripheral end surface (5) of the wafer (2), and exposes a peripheral edge portion of the first surface (3) in the supporting step (S3).

[B5] The manufacturing method (S1 to S9) for the semiconductor device (SD) according

to any one of B1 to B4, wherein the adhesive member (76) exposes a peripheral edge portion of the supporting member (51) in the supporting step (S3).

[B6] The manufacturing method (S1 to S9) for the semiconductor device (SD) according to any one of B1 to B5, wherein the wafer (2) that has the first surface (3) as a device surface and the second surface (4) as a non-device surface is prepared in the preparation step (S1).

[B7] The manufacturing method (S1 to S9) for the semiconductor device (SD) according to B6, wherein the wafer (2) that includes device structures (18) in the first surface (3) is prepared in the preparation step (S1), and the supporting member (51) supports the wafer (2) from the first surface (3) side such as to oppose all of the device structures (18) in the supporting step (S3).

[B8] The manufacturing method (S1 to S9) for the semiconductor device (SD) according to any one of B1 to B7, wherein the supporting member (51) includes at least one of glass, ceramic, silicon, silicon carbide, carbon, sapphire, gallium nitride, gallium oxide, resin, or metal.

[B9] The manufacturing method (S1 to S9) for the semiconductor device (SD) according to any one of B1 to B8, wherein the supporting member (51) has a diameter (D1) equal to or larger than a diameter (DW) of the wafer (2).

[B10] The manufacturing method (S1 to S9) for the semiconductor device (SD) according to any one of B1 to B9, wherein the supporting member (51) has a thickness (T1) equal to or thicker than a thickness (TW, TD, TE) of the wafer (2).

[B11] The manufacturing method (S1 to S9) for the semiconductor device (SD) according to any one of B1 to B10, wherein the processing step (S4) includes a thinning step (S41) of thinning the wafer (2) in a state where the wafer (2) is supported by the supporting member (51).

[B12] The manufacturing method (S1 to S9) for the semiconductor device (SD) according to any one of B1 to B11, wherein the processing step (S4) includes a wet step of processing the second surface (4) with a processing liquid in a state where the wafer (2) is supported by the supporting member (51).

[B13] The manufacturing method (S1 to S9) for the semiconductor device (SD) according to any one of B1 to B12, wherein the processing step (S4) includes a step of forming an electrode (77) on the second surface (4) in a state where the wafer (2) is supported by the supporting member (51).

[B14] The manufacturing method (S1 to S9) for the semiconductor device (SD) according to any one of B1 to B13, further comprising: a diameter reduction step (S2) of partially removing the peripheral end surface (5) of the wafer (2) before the supporting step (S3); and wherein the supporting member (51) is adhered to the first surface (3) side of the wafer (2) via the adhesive member (76) after the diameter reduction in the supporting step (S3).

[B15] The manufacturing method (S1 to S9) for the semiconductor device (SD) according to B14, wherein the wafer (2) that includes a bevel portion (8, 9) in the peripheral end surface (5) is prepared in the preparation step (S1), and the diameter reduction step (S2) includes a step of removing a part or all of the bevel portion (8, 9) from the peripheral end surface (5).

[B16] The manufacturing method (S1 to S9) for the semiconductor device (SD) according to any one of B1 to B15, further comprising: a second supporting step (S5) of supporting the wafer (2) from the second surface (4) side by a supporting member (61) of a plate shape after the processing step (S4); and a removing step (S6) of removing the supporting member (51) from the first surface (3) side in a state where the wafer (2) is supported by the second supporting member (61).

[B17] The manufacturing method (S1 to S9) for the semiconductor device (SD) according to B16, wherein the second supporting step (S5) includes a step of adhering the second supporting member (61) to the second surface (4) side via a second adhesive member (80).

[B18] The manufacturing method (S1 to S9) for the semiconductor device (SD) according to B17, wherein the second adhesive member (80) has a peeling condition different from a peeling condition of the adhesive member (76).

[B19] The manufacturing method (S1 to S9) for the semiconductor device (SD) according to B18, wherein the adhesive member (76) has a peeling condition having one of a thermal peeling type and an ultraviolet peeling type, and the second adhesive member (80) has a peeling condition having the other of the thermal peeling type and the ultraviolet peeling type.

[B20] The manufacturing method (S1 to S9) for the semiconductor device (SD) according to any one of B16 to B19, further comprising: a testing step (S7) of testing the wafer (2) in a state where the wafer (2) is supported by the second supporting member (61) after the removing step (S6).

[C1] A wafer support structure (75) comprising: a supporting member (51); and a wafer (2) that has a first surface (3) as a device surface, a second surface (4) as a non-device surface, and a peripheral end surface (5) which connects the first surface (3) and the second surface (4), and is arranged on the supporting member (51) in a posture in which the first surface (3) opposes the supporting member (51).

[C2] The wafer support structure (75) according to C1, wherein the wafer (2) includes an SiC single crystal.

[C3] The wafer support structure (75) according to C1 or C2, wherein the first surface (3) includes a first corner portion (6) including a bevel portion (8), and the second surface (4) includes a second corner portion (7) that does not include a bevel portion (9).

[C4] The wafer support structure (75) according to C3, wherein the bevel portion (8) opposes the supporting member (51) in a lamination direction.

[C5] The wafer support structure (75) according to C3 or C4, wherein the second corner portion (7) is angular.

[C6] The wafer support structure (75) according to any one of C1 to C5, wherein the second surface (4) is a ground surface.

[C7] The wafer support structure (75) according to any one of C1 to C6, wherein the peripheral end surface (5) is a ground surface.

[C8] The wafer support structure (75) according to any one of C1 to C7, wherein the wafer (2) has a thickness (TW, TD, TE) equal to or thinner than 100 μm.

[C9] The wafer support structure (75) according to any one of C1 to C8, wherein the supporting member (51) has a plate shape having a diameter (D1) equal to or larger than a diameter (DW) of the wafer (2), and the wafer (2) is arranged on the supporting member (51) at an interval inwardly from a peripheral edge of the supporting member (51).

[C10] The wafer support structure (75) according to any one of C1 to C9, wherein the supporting member (51) has a thickness (T1) equal to or thicker than a thickness (TW, TD, TE) of the wafer (2).

[C11] The wafer support structure (75) according to any one of C1 to C10, wherein the supporting member (51) includes at least one of glass, ceramic, silicon, silicon carbide, carbon, sapphire, gallium nitride, gallium oxide, resin, or metal.

[C12] The wafer support structure (75) according to any one of C1 to C11, further comprising: an electrode (77) that covers the second surface (4).

[C13] The wafer support structure (75) according to C12, wherein the electrode (77) exposes a peripheral edge portion of the second surface (4).

[C14] The wafer support structure (75) according to any one of C1 to C13, further comprising: a second supporting member (61) that is arranged on the second surface (4) of the wafer (2).

[C15] The wafer support structure (75) according to C14, wherein the second supporting member (61) has an annular plate shape, and is arranged on a peripheral edge portion of the second surface (4) such as to expose an inner portion of the second surface (4).

[C16] The wafer support structure (75) according to C15, wherein the second supporting member (61) has a diameter (D2) equal to or larger than a diameter (DW) of the wafer (2), and is arranged on the peripheral edge portion of the second surface (4) such as to protrude outwardly from the peripheral end surface (5).

[C17] The wafer support structure (75) according to any one of C14 to C16, wherein the second supporting member (61) has a thickness (T2) equal to or thicker than a thickness (TW, TD, TE) of the wafer (2).

[C18] The wafer support structure (75) according to any one of C14 to C17, wherein the second supporting member (61) includes at least one of glass, ceramic, silicon, silicon carbide, carbon, sapphire, gallium nitride, gallium oxide, resin, or metal.

[C19] A wafer support structure (75) comprising: a first supporting member (51) of a plate shape; a wafer (2) that has a first surface (3) as a device surface, a second surface (4) as a non-device surface, and a peripheral end surface (5) which connect the first surface (3) and the second surface (4), and is arranged on the first supporting member (51) in a posture in which the first surface (3) opposes the first supporting member (51); an electrode (77) that covers the second surface (4); and a second supporting member (61) of a an annular plate shape that is arranged on the electrode (77).

[C20] The wafer support structure (75) according to C19, wherein the first surface (3) includes a first corner portion (6) including a bevel portion (8), the second surface (4) is made of a ground surface and includes a second corner portion (7) that is angular, and the peripheral end surface (5) is made of a ground surface.

[D1] A wafer support structure (75) comprising: a supporting member (51); a wafer (2) that has a first surface (3) as a device surface, a second surface (4) as a non-device surface, and a peripheral end surface (5) which connects the first surface (3) and the second surface (4), and is arranged on the supporting member (51) in a posture in which the first surface (3) opposes the supporting member (51); and an adhesive member (76) that is interposed between the supporting member (51) and the first surface (3).

[D2] The wafer support structure (75) according to D1, wherein the adhesive member (76)

is located at an interval inwardly from a peripheral edge of the supporting member (51), and exposes a peripheral edge portion of the supporting member (51).

[D3] The wafer support structure (75) according to D1 or D2, wherein the adhesive member (76) is located at an interval inwardly from the peripheral end surface (5) of the wafer (2), and exposes a peripheral edge potion of the first surface (3).

[D4] The wafer support structure (75) according to any one of D1 to D3, wherein the first surface (3) includes a corner portion (6) including a bevel portion (8), and the adhesive member (76) exposes the bevel portion (8).

[D5] The wafer support structure (75) according to any one of D1 to D4, wherein the second surface (4) includes a corner portion (7) that does not include a bevel portion (9) and is angular.

[D6] The wafer support structure (75) according to any one of D1 to D5, wherein the second surface (4) is a ground surface.

[D7] The wafer support structure (75) according to any one of D1 to D6, wherein the peripheral end surface (5) is a ground surface.

[D8] The wafer support structure (75) according to any one of D1 to D7, wherein the supporting member (51) has a plate shape having a diameter (D1) equal to or larger than a diameter (DW) of the wafer (2), and the wafer (2) is arranged on the supporting member (51) at an interval inwardly from a peripheral edge of the supporting member (51).

[D9] The wafer support structure (75) according to any one of D1 to D8, wherein the supporting member (51) has a thickness (T1) equal to or thicker than a thickness (TW, TD, TE) of the wafer (2).

[D10] The wafer support structure (75) according to any one of D1 to D9, wherein the wafer (2) includes an SiC single crystal.

[D11] The wafer support structure (75) according to any one of D1 to D10, wherein the wafer (2) has a thickness (TW, TD, TE) equal to or thinner than 100 μm.

[D12] The wafer support structure (75) according to any one of D1 to D11, further comprising: an electrode (77) that covers the second surface (4).

[D13] The wafer support structure (75) according to any one of D1 to D12, further comprising: a second supporting member (61) that is arranged on the second surface (4); and a second adhesive member (80) that is interposed between the second surface (4) and the second supporting member (61).

[D14] A wafer support structure (75) comprising: a first supporting member (51) of a plate shape; a wafer (2) that has a first surface (3) as a device surface, a second surface (4) as a non-device surface, and a peripheral end surface (5) which connect the first surface (3) and the second surface (4), and is arranged on the first supporting member (51) in a posture in which the first surface (3) opposes the first supporting member (51); an electrode (77) that covers the second surface (4); a second supporting member (61) of an annular plate shape that is arranged on the electrode (77); a first adhesive member (76) that is interposed between the first supporting member (51) and the first surface (3); and a second adhesive member (80) that is interposed between the electrode (77) and the second supporting member (61).

[D15] The wafer support structure (75) according to D14, wherein the second adhesive member (80) has a peeling condition different from a peeling condition of the first adhesive member (76).

[D16] The wafer support structure (75) according to D14 or D15, wherein the first adhesive member (76) has a peeling condition having one of a thermal peeling type and an ultraviolet peeling type, and the second adhesive member (80) has a peeling condition having the other of the thermal peeling type and the ultraviolet peeling type.

[D17] The wafer support structure (75) according to any one of D14 to D16, wherein the first adhesive member (76) is located at an interval inwardly from the peripheral end surface (5) of the wafer (2), and exposes a peripheral edge potion of the first surface (3).

[D18] The wafer support structure (75) according to any one of D14 to D17, wherein the second adhesive member (80) is located at an interval inwardly from the peripheral end surface (5) of the wafer (2), and exposes a peripheral edge potion of the second surface (4).

[D19] The wafer support structure (75) according to any one of D14 to D18, wherein the electrode (77) exposes a peripheral edge portion of the second surface (4), and the second adhesive member (80) includes a portion that is adhered to the peripheral edge portion of the second surface (4).

[D20] The wafer support structure (75) according to D19, wherein the first surface (3) includes a first corner portion (6) including a bevel portion (8), the second surface (4) is made of a ground surface and includes a second corner portion (7) that is angular, and the peripheral end surface (5) is made of a ground surface.

[E1] A wafer support structure (75) comprising: a wafer (2) that has a first surface (3) as a device surface, a second surface (4) as a non-device surface, and a peripheral end surface (5) which connects the first surface (3) and the second surface (4); and a supporting member (61) that is arranged on a peripheral edge portion of the second surface (4) such as to expose an inner portion of the second surface (4).

[E2] The wafer support structure (75) according to E1, wherein the wafer (2) includes an SiC single crystal.

[E3] The wafer support structure (75) according to E1 or E2, wherein the first surface (3) includes a first corner portion (6) including a bevel portion (8), and the second surface (4) includes a second corner portion (7) that does not include a bevel portion (9).

[E4] The wafer support structure (75) according to E3, wherein the bevel portion (8) opposes the supporting member (61) in a lamination direction.

[E5] The wafer support structure (75) according to E3 or E4, wherein the second corner portion (7) is angular.

[E6] The wafer support structure (75) according to any one of E1 to E5, wherein the second surface (4) is a ground surface.

[E7] The wafer support structure (75) according to any one of E1 to E6, wherein the peripheral end surface (5) is a ground surface.

[E8] The wafer support structure (75) according to any one of E1 to E7, wherein the wafer (2) has a thickness (TW, TD, TE) equal to or thinner than 100 μm.

[E9] The wafer support structure (75) according to any one of E1 to E8, wherein the supporting member (61) protrudes outwardly from the peripheral end surface (5).

[E10] The wafer support structure (75) according to any one of E1 to E9, wherein the supporting member (61) has an annular plate shape.

[E11] The wafer support structure (75) according to E10, wherein the supporting member (61) has a diameter (D2) equal to or larger than a diameter (DW) of the wafer (2).

[E12] The wafer support structure (75) according to any one of E1 to E11, wherein the supporting member (61) has a thickness (T2) equal to or thicker than a thickness (TW, TD, TE) of the wafer (2).

[E13] The wafer support structure (75) according to any one of E1 to E12, wherein the

supporting member (61) includes at least one of glass, ceramic, silicon, silicon carbide, carbon, sapphire, gallium nitride, gallium oxide, resin, or metal.

[E14] The wafer support structure (75) according to any one of E1 to E13, further comprising: an electrode (77) that covers the second surface (4).

[E15] The wafer support structure (75) according to E14, wherein the supporting member

(61) is arranged on the electrode (77), and covers a peripheral edge portion of the second surface (4) across the electrode (77).

[E16] The wafer support structure (75) according to E14 or E15, wherein the electrode (77) exposes a peripheral edge portion of the second surface (4), and the supporting member (61) opposes a portion of the peripheral edge portion of the second surface (4) that is exposed from the electrode (77).

[E17] The wafer support structure (75) according to any one of E1 to E16, further comprising: an adhesive member (80) that is interposed between the supporting member (61) and the second surface (4).

[E18] The wafer support structure (75) according to E17, wherein the adhesive member

(80) is located at an interval inwardly from the peripheral end surface (5) of the wafer (2), and exposes a peripheral edge potion of the second surface (4).

[E19] A wafer support structure (75) comprising: a wafer (2) that has a first surface (3) as a device surface, a second surface (4) as a non-device surface, and a peripheral end surface (5) which connect the first surface (3) and the second surface (4); an electrode (77) that covers the second surface (4); a supporting member (61) of an annular plate shape that is arranged on the electrode (77); and an adhesive member (80) that is interposed between the electrode (77) and the supporting member (61).

[E20] The wafer support structure (75) according to E19, wherein the electrode (77) exposes a peripheral edge portion of the second surface (4), and the adhesive member (80) includes a portion that is adhered to the peripheral edge portion of the second surface (4).

While specific embodiments have been described in detail above, these are merely specific examples used to clarify the technical contents. The various technical ideas extracted from this description can be combined as appropriate with each other without being limited by the order of description, the order of configuration examples, the order of modification examples, and the like in this description.

What is claimed is:

1. A manufacturing method for a semiconductor device comprising:
a preparation step of preparing a wafer that has a first surface on one side and a second surface on the other side;
a first supporting step of supporting the wafer from the first surface side by a first member of a plate shape;
a thinning step of thinning the wafer in a state where the wafer is supported by the first member;
a second supporting step of supporting the wafer from a peripheral edge portion side of the second surface by a second member of a plate shape that exposes an inner portion of the second surface after the thinning step; and
a removing step of removing the first member from the first surface side in a state where the wafer is supported by the second member.

2. The manufacturing method for the semiconductor device according to claim 1,
wherein the wafer including an SiC single crystal is prepared in the preparation step.

3. The manufacturing method for the semiconductor device according to claim 1,
wherein the wafer that has the first surface as a device surface and the second surface as a non-device surface is prepared in the preparation step.

4. The manufacturing method for the semiconductor device according to claim 3,
wherein the wafer that has device structures in the first surface is prepared in the preparation step,
the first member supports the wafer from the first surface side such as to oppose the device structures in the first supporting step, and
the second member supports the wafer from the peripheral edge portion side of the second surface so as not to oppose the device structures in the second supporting step.

5. The manufacturing method for the semiconductor device according to claim 1,
wherein the wafer that has a thickness equal to or thicker than 150 μm is prepared in the preparation step, and
the wafer is thinned to a thickness thinner than 150 μm in the thinning step.

6. The manufacturing method for the semiconductor device according to claim 1, wherein the wafer that has a diameter equal to or larger than 6 inches is prepared in the preparation step.

7. The manufacturing method for the semiconductor device according to claim 1, wherein the first member includes at least one of glass, ceramic, silicon, silicon carbide, carbon, sapphire, gallium nitride, gallium oxide, resin, or metal.

8. The manufacturing method for the semiconductor device according to claim 1, wherein the first member has a diameter equal to or larger than a diameter of the wafer.

9. The manufacturing method for the semiconductor device according to claim 1, wherein the first member has a thickness equal to or thicker than a thickness of the wafer.

10. The manufacturing method for the semiconductor device according to claim 1, wherein the second member has an annular plate shape.

11. The manufacturing method for the semiconductor device according to claim 1, wherein the second member includes at least one of glass, ceramic, silicon, silicon carbide, carbon, sapphire, gallium nitride, gallium oxide, resin, or metal.

12. The manufacturing method for the semiconductor device claim 1, wherein the second member has a diameter equal to or larger than a diameter of the wafer.

13. The manufacturing method for the semiconductor device according to claim 1, wherein the second member has a thickness equal to or thicker than a thickness of the wafer.

14. The manufacturing method for the semiconductor device according to claim 1,
wherein the first member is adhered to the first surface side via a first adhesive member in the first supporting step, and
in the second supporting step, the second member is adhered to the second surface side via a second adhesive member.

15. The manufacturing method for the semiconductor device according to claim 14,
wherein the second adhesive member has a peeling condition different from a peeling condition of the first adhesive member.

16. The manufacturing method for the semiconductor device according to claim 1, further comprising:
a diameter reduction step of partially removing a peripheral end surface of the wafer before the first supporting step; and
wherein the first member supports the wafer after the diameter reduction in the first supporting step, and
the second member supports the wafer after the diameter reduction in the second supporting step.

17. The manufacturing method for the semiconductor device according to claim 16,
wherein the wafer that includes a bevel portion in the peripheral end surface is prepared in the preparation step, and
a part or all of the bevel portion is removed from the peripheral end surface in the diameter reduction step.

18. The manufacturing method for the semiconductor device according to claim 1, further comprising:
a step of forming an electrode on the second surface after the thinning step; and
wherein the second supporting step is performed after the forming step of the electrode.

19. The manufacturing method for the semiconductor device according to claim 1, further comprising:
a testing step of testing the wafer in a state where the wafer is supported by the second member after the removing step; and
a second removing step of removing the second member from the second surface side after the testing step.

20. A wafer support structure comprising:
a supporting member; and
a wafer that has a first surface as a device surface, a second surface as a non-device surface, and peripheral end surface which connects the first surface and the second surface, and is arranged on the supporting member in a posture in which the first surface opposes the supporting member.
